(19) United States
(12) Patent Application Publication
(10) Pub. No.: US 2026/0226082 A1
(43) Pub. Date: Aug. 6, 2026

(54) PHOSPHORUS-CONTAINING (METH)ACRYLOYL COMPOUND, PHOSPHORUS-CONTAINING VINYL BENZYL COMPOUND, PRODUCTION METHODS THEREFOR, FLAME-RETARDANT RESIN COMPOSITION AND LAMINATED BOARD FOR ELECTRONIC CIRCUIT BOARD CONTAINING SAME

(71) Applicant: NIPPON STEEL CHEMICAL & MATERIAL CO., LTD., Tokyo (JP)

(72) Inventor: Tsugutoshi WASANO, Tokyo (JP)

(73) Assignee: NIPPON STEEL CHEMICAL & MATERIAL CO., LTD., Tokyo (JP)

(21) Appl. No.: 19/149,860

(22) PCT Filed: Feb. 5, 2024
(86) PCT No.: PCT/JP2024/003660

§ 371 Date: Jul. 22, 2025

(30) Foreign Application Priority Data
Feb. 14, 2023 (JP) 2023-020688
Feb. 14, 2023 (JP) 2023-020692

(51) Int. Cl. C07F 9/40; C08F 112/34; C08F 122/20; C09D 5/18; C09D 125/18; C09D 135/02; H05K 1/03

(52) U.S. Cl. CPC C07F 9/4087; C08F 112/34; C08F 122/20; C09D 5/18; C09D 125/18; C09D 135/02; H05K 1/0326; H05K 2201/012

(57) ABSTRACT

Provided are a phosphorus-containing compound which is useful as a reactive phosphorus-based flame retardant and has excellent heat resistance and dielectric properties in a cured product, a curable resin composition including the same, and a cured product thereof. A phosphorus-containing (meth)acryloyl compound or a phosphorus-containing vinylbenzyl ether compound characterized by being represented by general formula (1). In the general formula (1), m is a number of 1 to 20, n1 is each independently a number of 1 to 4, Ar is an aromatic ring having 6 to 30 carbon atoms optionally having a substituent, and R1 is each independently a substituent represented by general formula (2) or general formula (3A) or (3B).

### TECHNICAL FIELD

The present invention relates to a reactive phosphorus compound, particularly a phosphorus-containing (meth)acryloyl compound and a phosphorus-containing vinylbenzyl compound, which are useful as reactive flame retardants for plastic materials.

### BACKGROUND ART

Plastic materials have been used in a wide range of applications, from building materials to electrical and electronic devices, due to their excellent mechanical properties and molding processability. However, most plastic materials are flammable, and therefore flame retardation is required for safety against heat generation and ignition as well as fire in applications such as electrical and electronic products, office automation equipment, and communication equipment.

As flame retardation technology for plastic materials, additive flame retardants such as halogen-based flame retardants, inorganic-based flame retardants, and phosphorus-based flame retardants and the like are generally added regardless of the type of resin or application. However, it has been pointed out that among these, the halogen-based flame retardants that are mainly based on bromine may be a source of highly carcinogenic dioxins, and there is a move towards restricting their use in response to the recent trend to reduce environmentally hazardous substances. Also, the inorganic-based flame retardants such as magnesium hydroxide and aluminum hydroxide and the like have a flame retardation effect due to their endotherm, however, a large amount of addition is required to be added in large amounts in order to achieve sufficient flame retardation, resulting in a decrease of various properties of plastic molded products. For this reason, phosphorus-based flame retardants have been widely used, which do not generate harmful substances and enable flame retardation with relatively small amounts added. However, effects on their properties cannot be avoided, such as a decrease in processability due to bleed-out and the like, a reduction in glass transition temperature, and the like.

In order to solve these problems of these additive flame retardants, reactive flame retardants that contain phosphorus atoms as a flame retardant component and have a reactive group, have been developed and widely used. As reactive flame retardants capable of being applied to epoxy resin compositions that are widely used in the electronic and electrical fields, for example, Patent Literature 1 discloses, as a curing agent for epoxy resins, a phenolic resin obtained by reacting bisphenol A with formaldehyde to obtain hydroxymethylbisphenol A, followed by reaction with 9,10-dihydro-9-oxa-10-phosphaphenanthrene-10-oxide (hereinafter abbreviated as “DOPO”). Patent Literature 2 discloses a phosphorus-containing epoxy resin obtained by reacting DOPO with quinones followed by reacting the reacted product with an epoxy resin. These resins solve the problems of processability such as bleed-out of a flame retardant, and are not deteriorated in thermal properties such as heat resistance. As described above, using the reactive flame retardant in comparison to an additive-type flame retardant, generally makes it possible to compensate for defects of the additive-type flame retardant, thereby leading to development of many flame-retardant epoxy resins and the like.

In recent years, however, in the field of electronic and electrical materials where flame retardancy is essential, the rapid evolution of electronic devices, represented by smartphones, has led to a change in properties required for resin components containing a flame retardant to those more advanced. Particularly in the information and communications field, frequency of signals has become higher involving an increased amount of information processed, and in order to reduce a transmission loss, resin components with a low dielectric constant and low dielectric loss tangent, which are used in this field have been strongly required. Therefore, in the field of electronic and electrical materials, represented by circuit boards, radically polymerizable resins that can achieve lower dielectric constants and lower dielectric loss tangents have come to be widely used in place of epoxy resins. Thus, there have been demands for not only a flame retardant in which a reactive group is reactive with an epoxy group or an epoxy resin, but also a halogen-free flame retardant with a low dielectric constant and a low dielectric loss tangent that can react with a radically polymerizable resin.

Patent Literatures 3 and 4 disclose, as a halogen-free flame retardant having a radically polymerizable functional group, vinylbenzyl ether compounds including a DOPO backbone. Moreover, Patent Literatures 5 and 6 disclose vinylbenzyl compounds or (meth)acryloyl compounds including a phosphate ester structure. However, these compounds cannot be said to have satisfactory characteristics in terms of a low dielectric constant and low dielectric tangent that have been currently required, still having resulted in no flame retardant containing a radically polymerizable group, which satisfies thermal properties such as halogen-free flame retardancy and heat resistance and dielectric properties.

### CITATION LIST

### Patent Literature

Patent Literature 1: JP2013-166938A
Patent Literature 2: JP11-279258A
Patent Literature 3: JP2004-331537A
Patent Literature 4: JP2004-277322A
Patent Literature 5: JP2022-16423A
Patent Literature 6: JP2022-16422A

### SUMMARY OF INVENTION

Accordingly, a problem to be solved by the present invention is to provide a phosphorus-containing compound that is useful as a reactive phosphorus-based flame retardant and has excellent heat resistance and dielectric properties in a cured product, a curable resin composition containing the same, and a cured product thereof.

The present inventors have found as a result of diligent investigation on the above-described problems that, as a first invention, a phosphorus-containing (meth)acryloyl compound having a specific structure has excellent heat resistance and dielectric properties, leading to completion of the present invention.

Namely, the first invention is a phosphorus-containing (meth)acryloyl compound characterized by being represented by general formula (1A):

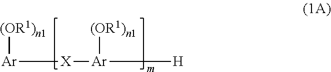

wherein, in the general formula (1A), m is a number of 1 to 20, n1 is each independently a number of 1 to 4, Ar is an aromatic ring having 6 to 30 carbon atoms optionally having a substituent, R1 is each independently a substituent represented by general formula (2A) or general formula (3A), provided that the compound contains at least one substituent represented by the general formula (2A) and at least one substituent represented by the general formula (3A), and X represents a linking group and is each independently oxygen, sulfur, a substituted or unsubstituted alkylene having 1 to 20 carbon atoms, a substituted or unsubstituted cycloalkylene having 3 to 20 carbon atoms, or an aralkylene having 8 to 32 carbon atoms,

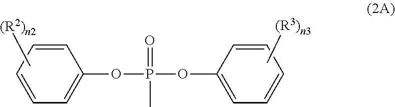

wherein, in the general formula (2A), R2 and R3 are each independently a linear or branched alkyl group having 1 to 5 carbon atoms, and n2 and n3 are each independently a number of 0 to 5,

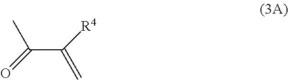

wherein R4 is hydrogen or a methyl group.

The present invention is suitably the above-described phosphorus-containing (meth)acryloyl compound characterized by being represented by the following general formula (4A):

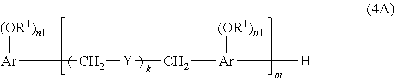

wherein, in the general formula (4A), R1, n1, and m are as defined for the general formula (1A), Y is an aromatic cyclic group having 6 to 30 carbon atoms optionally having a substituent, k is 0 or 1, and Ar represents an aromatic group derived from an aromatic compound represented by the following general formula (5), (6), (7), or (8):

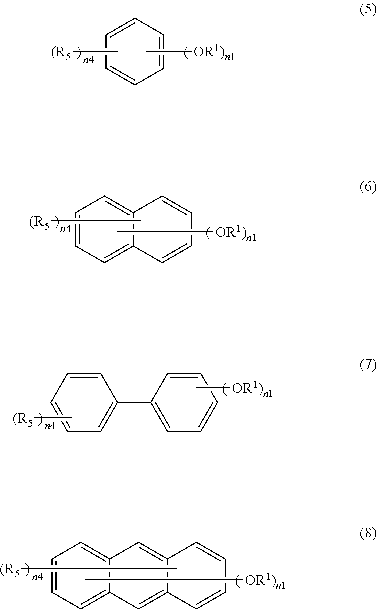

wherein, in the general formulae (5), (6), (7), and (8), R5 is each independently an alkyl group having 1 to 10 carbon atoms, or an alkoxy group having 1 to 10 carbon atoms, n4 is an integer of 0 to 4, and R1 and n1 are as defined for the general formula (1A).

The present invention is suitably the above-described phosphorus-containing (meth)acryloyl compound having a phosphorus content of 1.5 to 12.0% by weight.

The present invention is a method for producing the above-described phosphorus-containing (meth)acryloyl compound characterized by comprising reacting a phosphorus-containing phenolic compound represented by general formula (9) with one or more of (meth)acrylic acid, a (meth)acryloyl halide, or (meth)acrylic anhydride,

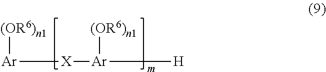

wherein, in the general formula (9), m, n1, Ar, and X are as defined for the general formula (1A), and R6 is hydrogen or the substituent represented by the general formula (2A) above.

The present invention is a flame-retardant resin composition characterized in that the composition is obtained by adding one or more of a thermosetting resin or a thermoplastic resin to the above-described phosphorus-containing (meth)acryloyl compound. The present invention is a laminated board for electronic circuit boards obtained by using the above-described flame-retardant resin composition.

The present inventors have found as a result of diligent investigation on the above-described problems that, as a second invention, a phosphorus-containing vinylbenzyl compound having a specific structure has excellent heat resistance and dielectric properties, leading to completion of the present invention.

Namely, the present invention is a phosphorus-containing vinylbenzyl ether compound characterized by being represented by general formula (1B):

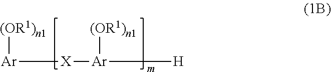

wherein, in the general formula (1B), m is a number of 1 to 20, n1 is each independently a number of 1 to 4, Ar is an aromatic ring having 6 to 30 carbon atoms optionally having a substituent, R1 is each independently a substituent represented by general formula (2B) or a vinylbenzyl group represented by general formula (3B), provided that the compound contains at least one substituent represented by the general formula (2B) and at least one substituent represented by the general formula (3B), and X represents a linking group and is each independently oxygen, sulfur, a substituted or unsubstituted cycloalkylene having 3 to 20 carbon atoms, or an aralkylene having 8 to 32 carbon atoms,

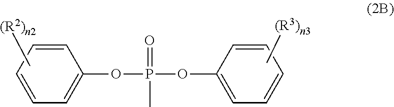

wherein, in the general formula (2B), R2 and R3 are each independently a linear or branched alkyl group having 1 to 5 carbon atoms, and n2 and n3 are each independently a number of 0 to 5.

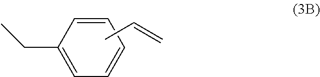

The present invention is suitably the phosphorus-containing vinylbenzyl ether compound characterized by being represented by the following general formula (4B):

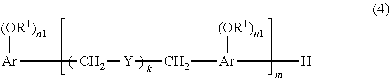

wherein, in the general formula (4B), R1, n1, and m are as defined for the general formula (1B), Y is an aromatic cyclic group having 6 to 30 carbon atoms optionally having a substituent, k is 0 or 1, and Ar represents an aromatic group derived from an aromatic compound represented by the following general formula (5), (6), (7), or (8):

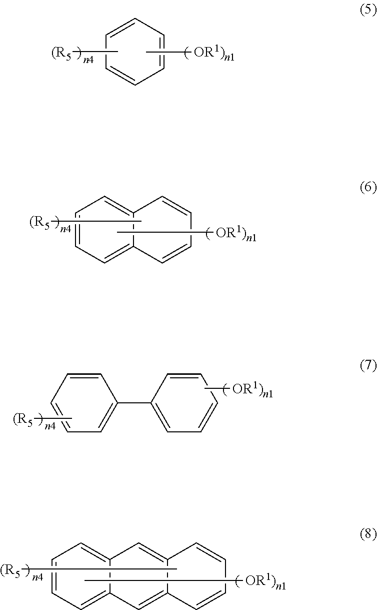

wherein, in the general formulae (5), (6), (7), and (8), R5 is each independently an alkyl group having 1 to 10 carbon atoms or an alkoxy group having 1 to 10 carbon atoms, n4 is an integer of 0 to 4, and R1 and n1 are as defined for the general formula (1B).

The present invention is suitably the above-described phosphorus-containing vinylbenzyl compound having a phosphorus content of 1.5 to 12.0% by weight. The present invention is a method for producing the above-described phosphorus-containing vinylbenzyl ether compound, characterized by comprising reacting a phosphorus-containing phenolic compound represented by general formula (9) with a vinylbenzyl halide.

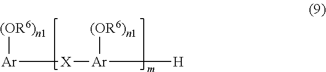

wherein, in the general formula (9B), m, n1, Ar, and X are as defined for the general formula (1B), and R6 is hydrogen or the substituent represented by the general formula (2B) above.

The present invention is a flame-retardant resin composition characterized in that the composition is obtained by adding one or more of a thermosetting resin or a thermoplastic resin to the phosphorus-containing vinylbenzyl ether compound. The present invention is a laminated board for electronic circuit boards obtained by using the above-described flame-retardant resin composition.

The phosphorus-containing (meth)acryloyl compound or the phosphorus-containing vinylbenzyl compound of the present invention has excellent heat resistance and dielectric properties and is very useful as a reactive-type phosphorus-based flame retardant for reducing a transmission loss at high frequencies accompanying an increase in the amount of information processed in electronic devices.

### DESCRIPTION OF EMBODIMENTS

First, the phosphorus-containing (meth)acryloyl compound of the first present invention will be described in detail.

In the description of the present invention, with regard to names of an acrylic resin, an acrylic compound, an acrylate compound, and the like, according to common practice, for example, both “acryloyl” and “methacryloyl” may be collectively referred to as “(meth)acryloyl”, both “acryl” and “methacryl” may be collectively referred to as “(meth)acryl”, and both “acrylate” and “methacrylate” may be collectively referred to as “(meth)acrylate”.

The phosphorus-containing (meth)acryloyl compound or phosphorus-containing phenolic compound includes not only a single compound but also a mixture (resins).

The phosphorus-containing (meth)acryloyl compound of the present invention is represented by the following general formula (1A):

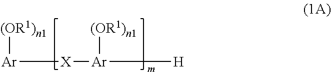

In the general formula (1A) above, m is the number of repetitions and indicates a number of 1 to 20. The phosphorus-containing (meth)acryloyl compound (resin) is usually a mixture of multiple compounds with the different numbers of repetitions, and an average value (number-average value) of m is in the range of 0.1 to 15, preferably 0.5 to 10, and more preferably 1.0 to 5.

Ar is each independently a substituted or unsubstituted aromatic cyclic group having 3 to 30 carbon atoms. Examples of the aromatic cyclic groups include, but are not limited to, compounds in which one or two hydrogen atoms have been removed from monocyclic aromatic compounds such as benzene, furan, pyrrole, thiophene, imidazole, pyrazole, oxazole, isoxazole, thiazole, isothiazole, pyridine, pyrimidine, pyridazine, pyrazine, and triazine; compounds in which one or two hydrogen atoms have been removed from fused-ring aromatic compounds such as naphthalene, anthracene, phenalene, phenanthrene, quinoline, isoquinoline, quinazoline, phthalazine, pteridine, coumarin, indole, benzimidazole, benzofuran, and acridine, and the like. Compounds in combinations of two or more of these aromatic compounds may also be used and examples thereof include compounds in which one or two hydrogen atoms have been removed from ring-aggregated aromatic compounds such as biphenyl, binaphthalene, bipyridine, bithiophene, phenylpyridine, phenylthiophene, terphenyl, diphenylthiophene, and quaterphenyl, and the like.

Specifically, Ar is preferably a group derived from one or more selected from aromatic hydroxy compounds represented by the following general formula (5), (6), (7), or (8)

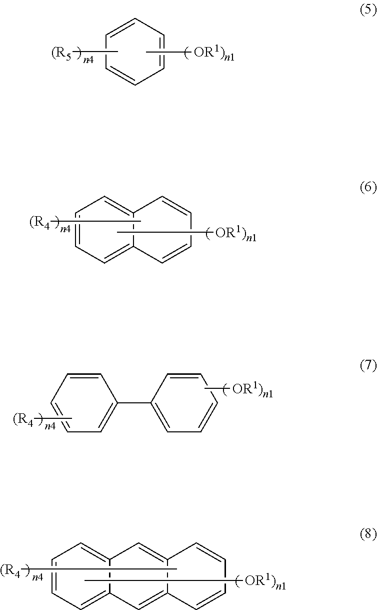

In the general formulae (5), (6), (7), and (8), R4 represents a substituent on the aromatic ring and is each independently an alkyl group having 1 to 10 carbon atoms and an alkoxy group having 1 to 10 carbon atoms. n4 is an integer of 0 to 4.

The alkyl group having 1 to 10 carbon atoms is not particularly limited, but includes a methyl group, an ethyl group, a propyl group, an isopropyl group, a n-butyl group, an isobutyl group, a sec-butyl group, a tert-butyl group, a n-pentyl group, an isopentyl group, a tert-pentyl group, a neopentyl group, a 1,2-dimethylpropyl group, a n-hexyl group, an isohexyl group, a n-nonyl group, a cyclopropyl group, a cyclobutyl group, a cyclopentyl group, a cyclohexyl group, a cycloheptyl group, a cyclooctyl group, and a cyclononyl group.

The alkoxy group having 1 to 10 carbon atoms is not particularly limited, but examples thereof include a methoxy group, an ethoxy group, a propoxy group, an isopropoxy group, a butoxy group, a pentyloxy group, a hexyloxy group, a 2-ethylhexyloxy group, an octyloxy group, a nonyloxy group, and the like.

These substituents may be used singly or in combination of two or more thereof.

In the general formulae (1A), (5), (6), (7), and (8), R1 represents a substituent represented by the following general formulae (2A) or (3A), and n1 is an integer of 1 to 4.

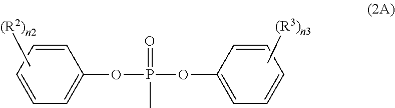

In the general formula (2A), R2 and R3 are each independently a linear or branched alkyl group having 1 to 5 carbon atoms.

Specific examples of the alkyl groups having 1 to 5 carbon atoms include a methyl group, an ethyl group, a propyl group, an isopropyl group, a n-butyl group, an isobutyl group, a tert-butyl group, a n-pentyl group, an isopentyl group, a neopentyl group, and the like. Among these, from the viewpoint of reactivity in production and availability, a methyl group is particularly preferred.

n2 and n3 are each independently an integer of 0 to 5 and preferably an integer of 0 to 2. When n2 or n3 are 1 or greater, substitution positions of n2 or n3 on the aromatic ring are not limited, but in order to prevent hydrolysis of a phosphate ester, they are preferably ortho positioned to oxygen.

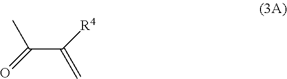

wherein R4 represents hydrogen or a methyl group.

In the general formulae (1A), (5), (6), (7) and (8), n1 represents the number of substitutions of the (meth)acryloyl group represented by the general formula (2A) or general formula (3A), bonded to each benzene ring. Here, n1 is an integer of 1 or greater and 5 or less.

The phosphorus-containing (meth)acryloyl compound of the present invention simultaneously has structures represented by the general formula (2A) and the general formula (3A) above. Including the structure of the general formula (2A) enables the phosphorus-containing (meth)acryloyl compound of the present invention to exhibit flame retardancy, and including the (meth)acryloyl group represented by the general formula (3A) enables a flame-retardant component to be fixed in a cured product, particularly in a vinyl resin system, and to inhibit heat resistance from being reduced without bleed out of the component.

It is to be noted that the phosphorus-containing (meth)acryloyl compound (mixture) of the present invention may contain a reactive raw material, for example, a polyhydric hydroxy compound represented by general formula (20) described later, as long as the effect is not impaired.

The phosphorus-containing (meth)acryloyl compound of the present invention preferably has both substituents represented by the general formula (2A) and the general formula (3A) in its structure, but when the above compound has a molecular weight distribution resulting from a repeating unit represented by m, the phosphorus-containing (meth)acryloyl compound may include a structure in which all the R1 groups are represented by the general formula (2A) or a structure in which all the R1 groups are the substituents represented by the general formula (3A). With the proviso that in order to achieve flame retardancy and heat resistance in a favorable balanced manner, it is necessary to satisfy the following phosphorus content when m is taken as the average. That is, the phosphorus-containing (meth)acryloyl compound of the present invention has a phosphorus content of 1.5 to 12.0% by weight, preferably 2.0 to 11% by weight, and more preferably 3.0 to 10% by weight.

In the phosphorus-containing (meth)acryloyl compound of the present invention, the presence ratio of the substituent represented by the general formula (2A) (proportion of the number of moles of the general formula (2A) to the total number of moles of the general formula (2A) and the general formula (3A)) can also be calculated from the phosphorus content. The presence ratio of the phosphorus-containing substituent represented by the general formula (2A) is acceptable (is of no problem) as long as it is not 0 mol %, but a low phosphorus content tends to result in insufficient flame retardancy and a high phosphorous content leads to insufficient heat resistance, and therefore, the presence ratio is preferably 10 to 90 mol %, more preferably 25 to 80 mol %, and still more preferably 30 to 60 mol %. In other words, the presence ratio of the (meth)acryloyl substituent represented by the general formula (3A) is preferably 10 to 90 mol %, more preferably 20 to 75 mol %, and still more preferably 40 to 70 mol %.

The phosphorus-containing (meth)acryloyl compound (resin) of the present invention preferably has an average molecular weight (Mw) in the range of 300 to 2,000 and more preferably 500 to 1,500.

In the general formula (1A), X represents a linking group, and as is clarified from the description of the above chemical formula (1A), one of hydrogen atoms of the aromatic ring constituting an aromatic ring of Ar is bonded to “X”. X is each independently oxygen, sulfur, a substituted or unsubstituted alkylene having 1 to 20 carbon atoms, a substituted or unsubstituted cycloalkylene having 3 to 20 carbon atoms, or an aralkylene having 8 to 20 carbon atoms.

The alkylene is not particularly limited, but examples thereof include methylene, ethylene, propylene, 1-methylmethylene, 1,1-dimethylmethylene, 1-methylethylene, 1,1-dimethylethylene, 1,2-dimethylethylene, propylene, butylene, 1-methylpropylene, 2-methylpropylene, pentylene, and hexylene.

The cycloalkylene is not particularly limited, but examples thereof include cyclopropylene, cyclobutylene, cyclopentylene, cyclohexylene, cyclopentylene, cycloheptylene, cycloalkylenes represented by the following chemical formulae (9) to (12), and the like.

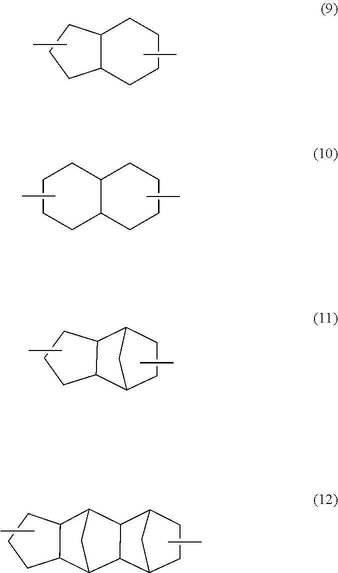

The aralkylene is not particularly limited, but examples thereof include aralkylenes represented by the following chemical formulae (13) to (19), and the like.

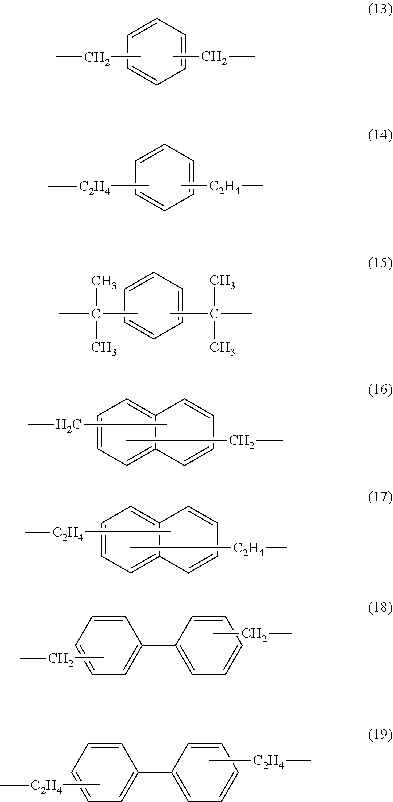

The cycloalkylene and the aralkylene may have a substituent. In this case, their substituents may be alkyl groups or alkoxy groups having 1 to 10 carbon atoms, or aryl groups. Examples of the aryl groups include a phenyl group, a tolyl group, a xylyl group, a hydroxyphenyl group, a benzyl group, a naphthyl group, and the like.

The phosphorus-containing (meth)acryloyl compound of the present invention is more preferably a structure represented by the following general formula (4).

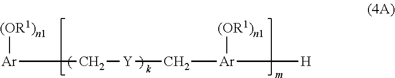

In the general formula (4A), R1, Ar, n1, and m are as defined for general formula (1).

k is 0 or 1. When k is 0, a linking group of Ar is a methylene group. Y represents an aromatic ring having 6 to 30 carbon atoms, and when k is 1, a linking group of Ar has the structure represented by formula (13), (16), or (18) above.

Next, a method for producing the phosphorus-containing (meth)acryloyl compound of the first present invention will be described. The phosphorus-containing (meth)acryloyl compound of the present invention is obtained by reacting a phosphorus-containing phenolic compound represented by general formula (9A) with (meth)acrylic acid, a (meth)acryloyl halide, or (meth)acrylic anhydride.

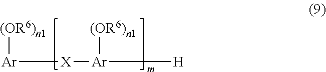

wherein in the general formula (9A), m, n1, Ar, and X are as defined for the general formula (1A), and R6 is hydrogen or the substituent represented by the general formula (2A) above. m, n1, Ar, X, and the general formula (2A) are as described in detail above. In formula (9), a substitution position of —OR6 on the aromatic ring is not particularly limited.

The phosphorus-containing phenolic compound represented by the general formula (9) preferably has a phosphorus content of 1.0 to 20% by weight, more preferably 3.0 to 10% by weight, and still more preferably 5.0 to 8.0% by weight. It has a hydroxyl group equivalent of preferably 100 to 1,000, more preferably 150 to 500, and still more preferably 200 to 350. The phosphorus-containing phenolic compound (resin) preferably has an average molecular weight (Mw) in the range of 200 to 1,900 and more preferably 400 to 1,400.

The phosphorus-containing phenolic compound represented by the general formula (9A) is an aromatic phosphate ester having one or more phenolic hydroxyl groups, and a production method thereof is similar to that of a general aromatic phosphate ester. That is, one example of the reaction form is an esterification reaction using a phosphorus oxyhalide (phosphoryl halide) and phenols as raw materials, and the corresponding phosphate ester can be obtained by a dehydrohalogenation reaction.

This esterification reaction is reversible, and in order to obtain a product efficiently, operations such as use of catalyst and removal of released hydrogen chloride from the reaction system are carried out.

The released hydrogen chloride is gas and increases in volume when gasified, so that it is released easily outside the reaction system in case of using highly reactive raw materials, but in case of using low-reactivity raw materials, the hydrogen halide is released in less amount and is likely to remain in the system, causing a reverse reaction, and therefore the reaction may not proceed. In such cases, it is effective to capture the generated hydrogen halide to prevent the reverse reaction, and amines may be used as hydrogen halide scavengers.

The phosphorus-containing phenolic compound represented by the general formula (9), is obtained by a reaction of, as raw materials, a polyhydric hydroxy compound: represented by the following general formula (20) corresponding to the general formula (9) with phenols and phosphorus oxyhalide: raw feedstocks for a phosphorus halide compound represented by the following general formula (21) corresponding to the above general formula (2A).

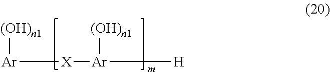

In the general formula (20), Ar, X, m, and n1 are as defined for the general formula (1A).

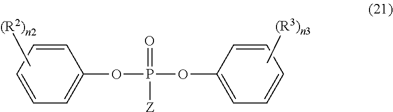

In the compound represented by general formula (21), R2, R3, n2, and n3 are as defined for the general formula (2A), and Z represents a halogen atom.

When the polyhydric hydroxy compound having a plurality of hydroxyl groups represented by the general formula (20), an essential raw material for the phosphorus-containing phenolic compound represented by the general formula (9), is reacted with phosphorus oxyhalide, however, a side reaction occurs in which the plurality of hydroxyl groups reacts with the phosphorus oxyhalide. So that, it is necessary to appropriately adjust a reaction order, a feed ratio of raw materials, reaction conditions, or the like, in order to efficiently obtain a target compound.

In this regard, instead of reacting the three raw materials of the polyhydric hydroxy compound represented by the general formula (20), the phenols and phosphorus oxyhalide which are the raw materials for the phosphorus halide compound represented by the general formula (9) at once, the phosphorus oxyhalide, for example, phosphorus oxychloride (POCl3), is reacted with the phenols first to obtain a phosphorus halide compound represented by the following general formula (21), and then the obtained phosphorus halide compound represented by the general formula (21) is reacted with the polyhydric hydroxy compound represented by the general formula (20), making it possible to efficiently obtain the target compound.

In this case, in the prior stage reaction, the phenols is compounded in a proportion of 2 mol per mole of the phosphorus oxyhalide. The phenols is preferably compounded in an amount within the range of 1.8 to 2.2 mol and more preferably 1.9 to 2.1 mol.

Examples of the polyhydric hydroxy compound represented by the general formula (20) include bisphenols such as bisphenol A, bisphenol F, bisphenol C, bisphenol K, bisphenol Z, bisphenol S, tetramethylbisphenol A, tetramethylbisphenol F, tetramethylbisphenol S, tetramethylbisphenol Z, dihydroxydiphenyl sulfide, and 4,4′-thiobis(3-methyl-6-t-butylphenol); dihydroxybenzenes such as catechol, resorcin, methylresorcin, hydroquinone, monomethylhydroquinone, dimethylhydroquinone, trimethylhydroquinone, mono-t-butylhydroquinone, and di-t-butylhydroquinone; hydroxynaphthalenes such as dihydroxynaphthalene, dihydroxymethylnaphthalene, and trihydroxynaphthalene; and novolac-type phenolic resins such as a phenol novolac resin, a cresol novolac resin, an aromatic group-modified phenol novolac resin, a bisphenol A novolac resin, a trishydroxyphenylmethane-type novolac resin, and a naphthol novolac resin.

In the case of the novolac-type phenolic resin, examples of its raw material phenols include phenol, cresol, xylenol, butylphenol, amylphenol, nonylphenol, butylmethylphenol, trimethylphenol, and phenylphenol, examples of the naphthols include 1-naphthol and 2-naphthol, and examples of raw material aldehydes include formaldehyde, acetaldehyde, propylaldehyde, butylaldehyde, valeraldehyde, capronaldehyde, benzaldehyde, chloraldehyde, bromoaldehyde, glyoxal, malonaldehyde, succinaldehyde, glutaraldehyde, adipic aldehyde, pimelic aldehyde, sebacic aldehyde, acrolein, crotonaldehyde, salicylaldehyde, phthalaldehyde and hydroxybenzaldehyde.

Phenols, which are raw materials for the phosphorus halide compound represented by the general formula (21), are preferably monohydric phenols that are either unsubstituted or substituted with an alkyl group having 1 to 6 carbon atoms, and specific examples thereof include phenol, o-cresol, m-cresol, p-cresol, ethylphenols, isopropylphenols, tertiary butylphenols, phenylphenols, 2,6-xylenol, and 2,6-diethylphenol.

These phenols may be used singly or in combination of two or more thereof.

Examples of the phosphorus oxyhalide, which is a raw material for the phosphorus halide compound represented by the general formula (9), include phosphorus oxychloride and phosphorus oxybromide.

Since the phosphorus-containing phenolic compound of the present invention can be obtained by reacting a hydroxyl group of the polyhydric hydroxy compound represented by the general formula (20) with the phosphorus halide compound represented by the general formula (21), adjusting a molar ratio of the compound of the general formula (21) to the hydroxyl group of the polyhydric hydroxy compound enables control of hydroxyl equivalent and phosphorus content. It is to be noted that the hydroxyl equivalent of the compound represented by the general formula (9) obtained by this reaction is measured and compared with the hydroxyl equivalent of the raw material of the general formula (20), then to enable calculation of presence proportion of the general formula (2A) in the general formula (9), and the obtained numerical value is equal to the presence proportion of the general formula (2A) in the general formula (1A) described above.

A reaction molar ratio of the phosphorus halide compound represented by the general formula (21) per mole of a hydroxyl group of the polyhydric hydroxy compound represented by the general formula (20), is preferably 0.1 to 0.9 mol, more preferably 0.2 to 0.8 mol, and still more preferably 0.3 to 0.7 mol. When it is 0.1 mol or less, the phosphorus content decreases, resulting in insufficient flame retardancy, which is not preferable.

In the case of 0.9 mol or more, the hydroxyl group that is a reactive group decreases in its amount, resulting in insufficient heat resistance and a higher viscosity, which is not preferable. This esterification reaction is reversible, and in order to obtain a product efficiently, operations such as use of catalyst or removal of released hydrogen chloride from the reaction system are carried out.

The released hydrogen chloride is gas and increases in volume when gasified, and therefore is easily released from the reaction system in case of using highly reactive raw materials, but, in case of using low reactive raw materials, the hydrogen halide is released in less amount and is likely to remain in the system, causing a reverse reaction, as a result of which the reaction may not proceed. In such cases, it is effective to capture the generated hydrogen halide to prevent the reverse reaction, and therefore amines may be used as hydrogen halide scavengers.

The reaction of the phosphorus-containing phenolic compound represented by formula (9) with (meth)acrylic acid, a (meth)acryloyl halide, or (meth)acrylic anhydride is not particularly limited, and can be carried out in the same manner as a normal (meth)acryloylation reaction of a phenolic compound.

For example, when (meth)acrylic acid is used, the phosphorus-containing phenolic compound represented by formula (3A) can be produced by a condensation reaction with 1 to 10 times the amount of (meth)acrylic acid relative to that of hydroxyl group in the presence of a strong acid catalyst such as sulfuric acid, p-toluenesulfonic acid, or methanesulfonic acid. This reaction needs to be carried out while removing the by-product condensed water from the system, and therefore a hydrocarbon-based solvent that is azeotropic with water, such as toluene, is used as a reaction solvent followed by heating the reaction liquid to approximately 70 to 140° C.

Also, the phosphorus-containing phenolic compound represented by formula (9) is reacted with a (meth)acryloyl halide or (meth)acrylic anhydride to be able to obtain the phosphorus-containing (meth)acryloyl compound of the present invention. Examples of the (meth)acryloyl halide that can be used include acryloyl halides such as acryloyl fluoride, acryloyl chloride, acryloyl bromide, and acryloyl iodide, and methacryloyl halides such as methacryloyl fluoride, methacryloyl chloride, methacryloyl bromide, and methacryloyl iodide.

In carrying out the present invention, as the (meth)acryloyl halide or (meth)acrylic anhydride, one or a mixture of two or more types of each thereof may be used. Among them, in terms of facilitation of availability, it is preferable in the present invention to use the (meth)acrylic chloride and/or (meth)acrylic anhydride.

The amount of (meth)acryloyl halide and/or (meth)acrylic anhydride used is 0.8 to 5 mol, preferably 0.95 to 4 mol per mole of a hydroxyl group of the phosphorus-containing phenolic compound to be used as a raw material. The amount of (meth)acrylic halide and/or (meth)acrylic anhydride used falling below the above range reduces heat resistance of the resulting phosphorus-containing (meth)acryloyl compound and increases the residual hydroxyl group in amount, thereby deteriorating the dielectric properties, which is not preferred, and also, the amount thereof used exceeding the above range reduces the reactor efficiency and increases the cost, which is not preferred.

When the (meth)acryloyl halide is used, hydrogen halide corresponding to the (meth)acrylic halide to be used is generated as a by-product, so that it is preferable to use a basic compound in combination and carry out the reaction while trapping the generated hydrogen halide. The basic compound is not particularly limited, and examples thereof can include aliphatic amines such as trimethylamine, triethylamine, diisopropylethylamine, tri-n-propylamine, triisopropylamine, tributylamine, N-methyl-diethylamine, N-ethyl-dimethylamine, and N-ethyl-diamylamine; aromatic amines such as N,N-dimethylaniline and diethylaniline; alicyclic amines such as N,N-dimethyl-cyclohexylamine and N,N-diethyl-cyclohexylamine; heterocyclic amines such as N,N-dimethylaminopyridine, N-methylmorpholine, diazabicycloundecene (DBU), diazabicyclononene (DBN), N-methylpyridine, and N-methylpyrrolidine; and diamines such as tetramethylethylenediamine and triethylenediamine. In particular preferred are, in terms of facilitation of availability, aliphatic amines such as trimethylamine and triethylamine, and pyridine.

The amount of basic compound used is, for example, 0.8 to 7 mol, preferably 0.95 to 5 mol per mole of a hydroxyl group of the phosphorus-containing phenolic compound to be used as a raw material. The amount of tertiary amine used falling below the above range does not allow hydrogen halide being completely trapped, causing corrosion of reaction equipment, and the amount of tertiary amine used exceeding the above range tends to raise a cost.

In carrying out the reaction with (meth)acrylic anhydride, it is not necessary to use a catalyst, however, in the case of a reaction which is unlikely to proceed, an ester catalyst, an acid catalyst, a base catalyst, or a Lewis acid catalyst can be used. Herein, examples of the ester catalyst include alkali metal (which includes sodium and potassium) salts of lower carboxylic acids, such as sodium acetate, potassium propionate, and sodium (meth)acrylate. Examples of the acid catalyst include inorganic acids such as sulfuric acid and boric acid; and organic acids such as methanesulfonic acid and para toluenesulfonic acid.

Also, examples of the base catalyst include, in the case of organic bases, nitrogen-containing aliphatic compounds such as triethylamine and triethylenediamine; and nitrogen-containing aromatic heterocyclic compounds such as pyridine and 4-(dimethylamino)pyridine. In addition, examples of the Lewis acid catalyst include aluminum chloride and zinc chloride.

The amount of catalyst used is preferably 10% or less and more preferably 5% or less, relative to the amount of (meth)acrylic anhydride to be used. When the amount of catalyst to be used exceeds the above range, it takes a long time to remove the catalyst, which is also likely to remain in a product, resulting in deterioration of the properties.

In the reaction of the phosphorus-containing phenolic compound represented by formula (9) with a (meth)acryloyl halide and/or (meth)acrylic anhydride, it is preferable to use an organic solvent as a reaction solvent and carry out the reaction in solution. The solvent that can be used is not particularly limited as long as it is not reactive with the phenolic compound and (meth)acrylic acid halide and/or (meth)acrylic anhydride, and examples of such a solvent include solvents such as tetrahydrofuran, dioxane, ethyl acetate, acetonitrile, benzene, toluene, xylene, dichloromethane, chloroform, carbon tetrachloride, dimethylformamide, dimethylacetamide, dimethylsulfoxide, hexamethylphosphoric triamide, and water, and these can be combined for use, if necessary.

In the reaction of the phosphorus-containing phenolic compound represented by formula (9) with a (meth)acrylic acid halide and/or (meth)acrylic acid anhydride, a reaction temperature is preferably −50 to 150° C. and when reacted at an elevated temperature, they have a likelihood of being polymerized, and therefore the reaction temperature is more preferably −25 to 100° C.

Also, a reaction time is appropriately set according to the set reaction temperature, but is preferably set in the range of 1 to 48 hours.

The reaction of the phosphorus-containing phenolic compound represented by formula (9) with (meth)acrylic acid, a (meth)acryloyl halide or (meth)acrylic anhydride may be carried out in the presence of a polymerization inhibitor. Adding the polymerization inhibitor can prevent the (meth)acrylic acid, (meth)acryloyl halide or (meth)acrylic anhydride to be reacted, and a (meth)acrylic acid ester to be a target product from being polymerized to produce an oligomer as a by-product.

Any publicly known polymerization inhibitor can be limitlessly used, and examples of the polymerization inhibitor include organic compounds such as hydroquinone, hydroxymonomethyl ether, t-butylcatechol, t-butylhydroquinone, 4-methoxyphenol, 4-methoxy-1-naphthol, and phenothiazine, as well as copper compounds such as copper chloride and copper sulfide, and these may be used in combination thereof.

After completion of this reaction, the resulting reaction liquid (reaction mixture) undergoes removal of reaction solvent by distillation, solvent replacement, or the like, if necessary, and is purified using means such as washing with water, activated carbon treatment, and silica gel chromatography, to produce the target (meth)acryloyl compound of the present invention.

Next, the phosphorus-containing vinylbenzyl compound of the second invention will be described in detail.

The phosphorus-containing vinylbenzyl compound of the present invention is represented by the following general formula (1B):

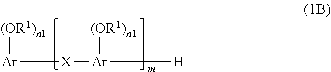

In the general formula (1B), m, Ar, and X have the same definition as m, Ar, and X in the general formula (1A).

In the general formula (1B) and formulae (5), (6), (7), and (8) representing the Ar group, R1 represents a substituent represented by the following general formula (2B) or (3B), and n1 is an integer of 1 to 4.

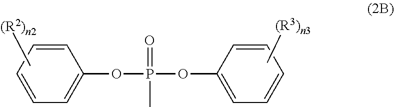

In the general formula (2B), R2 and R3 are each independently a linear or branched alkyl group having 1 to 5 carbon atoms.

Specific examples of the alkyl group having 1 to 5 carbon atoms include methyl, ethyl, propyl, isopropyl, n-butyl, isobutyl, tert-butyl, n-pentyl, isopentyl, and neopentyl. Among these, the methyl group is particularly preferred from the viewpoints of reactivity in production and facilitation of availability.

n2 and n3 are each independently an integer of 0 to 5, preferably an integer of 0 to 2. When n2 and n3 are 1 or more, substitution positions of n2 or n3 on the aromatic ring are not limited, but they are preferably in the ortho position with respect to oxygen in terms of prevention of hydrolysis of phosphate ester.

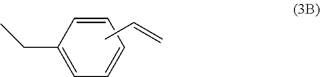

In formula (3B), a substitution position of the vinyl group on the benzene ring is not particularly limited, but it is preferably in the meta or para position with respect to the bonding position of the methylene chain.

In the general formula (1B) and formulae (5), (6), (7) and (8) representing the Ar group, n1 represents the number of substitutions of the vinylbenzyl group represented by the general formula (2B) or the general formula (3B), bonded to each benzene ring. Herein, n1 is an integer of 1 or greater and 5 or less.

The phosphorus-containing vinylbenzyl compound of the present invention simultaneously has the structures represented by the general formula (2B) and the general formula (3B) above. Inclusion of structure of the general formula (2B) enables the phosphorus-containing vinylbenzyl compound of the present invention to exhibit flame retardancy, and including the vinylbenzyl group represented by the general formula (3B) allows a flame-retardant component to be fixed in a cured product, particularly in a vinyl resin system, making it possible to inhibit deterioration in heat resistance without bleeding out of the component.

It is to be noted that the phosphorus-containing vinylbenzyl compound (mixture) of the present invention may contain a reactive raw material, for example, a polyhydric hydroxy compound represented by general formula (20) described later, as long as its effect is not impaired.

The phosphorus-containing vinylbenzyl compound of the present invention preferably has, in the structure, both the substituents represented by the general formula (2B) and the general formula (3B), but when having a molecular weight distribution resulting from a repeating unit represented by m, the phosphorus-containing vinylbenzyl compound may include a structure in which all the R1 groups are represented by the general formula (2B) or a structure in which all the R1 groups are substituents represented by the general formula (3B).

With the proviso that in order to achieve flame retardancy and heat resistance in a well-balanced manner, it is necessary for the compound to satisfy the following phosphorus content when m is taken as the average. That is, the phosphorus-containing vinylbenzyl compound of the present invention has a phosphorus content of 1.5 to 12.0% by weight, preferably 2.0 to 11% by weight, and more preferably 3.0 to 10% by weight.

In the phosphorus-containing vinylbenzyl compound of the present invention, the presence ratio of the substituent represented by the general formula (2B) (the proportion of the number of moles of the general formula (2B) to the total number of moles of the general formula (2B) and the general formula (3B)) can also be calculated from the phosphorus content. The presence ratio of the substituent represented by the general formula (2) is acceptable as long as it is not 0 mol %, but a low presence ratio tends to result in insufficient flame retardancy, on the contrary, a high presence ratio leads to insufficient heat resistance, so that the presence ratio is preferably 10 to 90 mol %, more preferably 25 to 80 mol %, and still more preferably 30 to 60 mol %. In other words, the presence ratio of the vinylbenzyl substituent represented by the general formula (3B) is preferably 10 to 90 mol %, more preferably 20 to 75 mol %, and still more preferably 40 to 70 mol %.

The phosphorus-containing vinylbenzyl compound (resin) of the present invention preferably has an average molecular weight (Mw) in the range of 300 to 2,300 and more preferably 500 to 2,000.

The phosphorus-containing vinylbenzyl compound of the present invention preferably has a structure represented by the following general formula (4B):

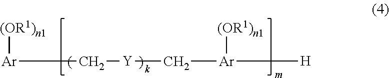

In formula (4B), R1, Ar, n1, and m are as defined for formula (1B).

k is 0 or 1. When k is 0, a linking group of Ar is a methylene group. Y represents an aromatic ring having 6 to 30 carbon atoms, and when k is 1, a linking group of Ar has a structure represented by formula (13), (16), or (18) above.

The phosphorus-containing vinylbenzyl ether compound of the second invention is obtained by reacting a phosphorus-containing phenolic compound represented by formula (9) with a vinylbenzyl halide.

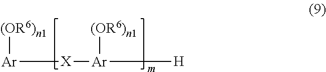

The phosphorus-containing phenolic compound represented by formula (9) is the same as that described above in production of the phosphorus-containing (meth)acryloyl compound of the first invention.

Examples of the vinylbenzyl halide to be used in the second invention include, but are not limited to, p-vinylbenzyl chloride, m-vinylbenzyl chloride, p-vinylbenzyl bromide, and m-vinylbenzyl bromide, which may be used singly or in admixture of two or more thereof.

Examples of a commercially available product include CMS-14 (p-vinylbenzyl chloride, manufactured by AGC SEIMI CHEMICAL CO., LTD.) and CMS-P (admixture of p-vinylbenzyl chloride and m-vinylbenzyl chloride, manufactured by AGC SEIMI CHEMICAL CO., LTD.).

The compounding proportion of the phosphorus-containing phenolic compound and the vinylbenzyl halide is 0.8 to 4.0 mol, preferably 0.95 to 2.0 mol, and more preferably 1.0 to 1.5 mol, of the vinylbenzyl halide with per mole of a hydroxyl group in the phosphorus-containing phenolic compound. The vinylbenzyl halide with an amount of less than 0.8 mol per mole of the phosphorus-containing phenolic compound, increases the amount of residual hydroxyl group, and reduces heat resistance, and the vinylbenzyl halide with an amount of exceeding 4.0 mol increases the amount of residual unreacted vinylbenzyl halide or excessively increases the amount of polymerized product due to a side reaction.

In the reaction of the phosphorus-containing phenolic compound represented by formula (9) with a vinylbenzyl halide, it is preferable to add an alkaline compound for the purpose of a reaction with a halogen of the vinylbenzyl halide and accelerating a reaction with the phosphorus-containing phenolic compound. Examples of the alkaline compound include alkali metal hydroxides such as lithium hydroxide, sodium hydroxide, and potassium hydroxide, alkaline earth metal hydroxides such as calcium hydroxide and magnesium hydroxide, and alkaline compounds of alkali metal carbonates such as sodium carbonate and potassium carbonate. Among them, in terms of a reaction acceleration effect and hydrolysis inhibition, the alkali metal carbonate is preferred. They may also be used singly or in combination of two or more thereof. Also, they may be used in solid form or in solution such as an aqueous solution, but preferred is an aqueous solution. The amount of alkaline compound used is 0.5 to 5.0 mol, preferably 1 to 4 mol, and more preferably 1.2 to 3 mol per mole of the vinylbenzyl halide. When the amount of alkaline compound used is less than 0.5 mol, the reaction does not proceed sufficiently. On the other hand, the amount thereof exceeding 5.0 mol requires a large amount of acid for neutralization, which is economically undesirable.

For the reaction, a catalyst can be used, if necessary. Examples of the catalyst to be used include, but are not limited to, various catalysts such as a tertiary amine such as benzyldimethylamine, quaternary ammonium salts such as tetramethylammonium chloride, tetramethylammonium bromide, and tetrabutylammonium bromide, phosphines such as triphenylphosphine and tris(2,6-dimethoxyphenyl)phosphine, phosphonium salts such as benzyltriphenylphosphonium chloride, tetrabutylphosphonium bromide, ethyltriphenylphosphonium bromide, and tetrabutylphosphonium iodide, and imidazoles such as 2-methylimidazole and 2-ethyl-4-methylimidazole. They may be used singly or in combination of two or more thereof. The amount of catalyst used is 10 parts by weight or less relative to 100 parts by weight of a raw material.

A solvent used in the reaction is not particularly limited, and examples thereof include hydrocarbons such as hexane, heptane, octane, decane, dimethylbutane, pentene, cyclohexane, methylcyclohexane, benzene, toluene, xylene, and ethylbenzene; alcohols such as methanol, ethanol, propanol, butanol, amyl alcohol, pentanol, hexanol, methyl amyl alcohol, heptanol, cyclohexanol, benzyl alcohol, and furfuryl alcohol; ethers such as ethyl ether, isopropyl ether, butyl ether, diisoamyl ether, methyl phenyl ether, ethyl phenyl ether, amyl phenyl ether, ethyl benzyl ether, dioxane, methyl furan, and tetrahydrofuran; ketones such as acetone, methyl acetone, methyl ethyl ketone, methyl propyl ketone, methyl butyl ketone, methyl amyl ketone, diethyl ketone, ethyl butyl ketone, dipropyl ketone, and cyclohexanone; methyl cellosolve, methyl cellosolve acetate, ethyl cellosolve, cellosolve acetate, ethylene glycol isopropyl ether, diethylene glycol dimethyl ether, methyl ethyl carbitol, propylene glycol monomethyl ether, dimethylformamide, and dimethyl sulfoxide, but are limited thereto. These may be used singly or in combination of two or more thereof. Also, when removing a salt produced in the reaction by washing with water, it is preferable to use a solvent that allows separation of an aqueous layer. Examples of the solvent include benzene, toluene, xylene, methyl ethyl ketone, and methyl isobutyl ketone.

The reaction may be carried out in the presence of a polymerization inhibitor. Addition of polymerization inhibitor can prevent the vinylbenzyl halide to be reacted or a vinylbenzyl ether compound to be a target product from being polymerized to produce an oligomer as a by-product. Any publicly known polymerization inhibitor can be limitlessly used, and examples of the polymerization inhibitor include organic compounds such as hydroquinone, hydroxymonomethyl ether, t-butylcatechol, t-butylhydroquinone, 4-methoxyphenol, 4-methoxy-1-naphthol, and phenothiazine, as well as copper compounds such as copper chloride and copper sulfide, and these may be combined for use.

After completion of this reaction, the obtained reaction liquid (reaction mixture) can undergo removal of the reaction solvent by distillation, solvent replacement, or the like, if necessary, and was purified using means such as washing with water, activated carbon treatment, and silica gel chromatography, to obtain the target vinylbenzyl ether compound of the present invention.

Next, a flame-retardant resin composition obtained by adding a curable resin or a thermoplastic resin to the phosphorus-containing (meth)acryloyl compound of the first invention or the phosphorus-containing vinylbenzyl compound of the second invention as an essential ingredient will be described.

In the flame-retardant resin composition of the present invention, a compounding proportion is not particularly limited, but it is preferable to compound, for example, the phosphorus-containing (meth)acryloyl compound, in an amount of 10 to 300 parts by weight, relative to 100 parts by weight of the total amount of curable resin and thermoplastic resin. The amount thereof is preferably 20 to 200 parts by weight and more preferably 50 to 150 parts by weight.

Examples of the curable resin include an unsaturated polyester resin, a curable maleimide resin, an epoxy resin, a polycyanate resin, a phenol resin, and one or more vinyl compounds having one or more polymerizable unsaturated hydrocarbon groups in the molecule, and preferably an epoxy resin and one or more vinyl compounds having one or more polymerizable unsaturated hydrocarbon groups in the molecule.

When the curable resin is an epoxy resin, it is preferably one or more epoxy resins selected from epoxy resins having two or more epoxy groups in one molecule.

Examples of such an epoxy resin include a cresol novolac-type epoxy resin, a triphenylmethane-type epoxy resin, a biphenyl epoxy resin, a naphthalene-type epoxy resin, a bisphenol A-type epoxy resin, and a bisphenol F-type epoxy resin. These may be used singly or in combination of two or more thereof. It is considered that the use of such epoxy resins minimizes an influence on the excellent dielectric properties and flowability of the curable resin composition of the present invention, and sufficiently enhances the heat resistance and adhesiveness of a cured product.

Also, when an epoxy resin is contained, a curing agent may be used in addition to the epoxy resin. The curing agent is not particularly limited, and examples thereof include a phenol-based curing agent, an amine-based compound, an amide-based compound, an acid anhydride-based compound, a naphthol-based curing agent, an active ester-based curing agent, a benzoxazine-based curing agent, and a cyanate ester-based curing agent. These may be used singly or in combination of two or more thereof.

Furthermore, when an epoxy resin is compounded, a curing accelerator can be used, if necessary. It is, for example, amines, imidazoles, organic phosphines, Lewis acids, and the like. The amount added is usually in the range of 0.2 to 5 parts by weight relative to 100 parts by weight of epoxy resin.

In the case of curable resins, which are one or more vinyl compounds having one or more polymerizable unsaturated hydrocarbon groups in the molecule (hereinafter also referred to as vinyl compounds), the type thereof is not particularly limited. In other words, the vinyl compounds may be any compounds capable of reacting with the phosphorus-containing (meth)acryloyl compound of the present invention to form a cross-link therein and then cure the compound. It is more preferably a compound in which the polymerizable unsaturated hydrocarbon group is a carbon-carbon unsaturated double bond, and more preferably a compound having two or more carbon-carbon unsaturated double bonds in the molecule.

The average number of carbon-carbon unsaturated double bonds (the number of vinyl groups (including substituted vinyl groups); also referred to as the number of terminal double bonds) with per molecule of the vinyl compounds as curable resins varies depending on the Mw of the vinyl compound, but is preferably 1 to 20 and more preferably 2 to 18. The terminal double bond, if small in number, tends to make it difficult to obtain a cured product with sufficient heat resistance. Also, the terminal double bond, excessive in number results in too high reactivity, and problems may arise, such as a decrease in the storage stability of the curable resin composition or a decrease in the flowability of the curable resin composition.

Examples of the above-described vinyl compound include a trialkenyl isocyanurate compound such as triallyl isocyanurate (TAIC), modified polyphenylene ether (PPE), an end of which has been modified with a (meth)acryloyl group or a styryl group, a polyfunctional (meth)acrylate compound having two or more (meth)acryloyl groups in the molecule, a vinyl compound (polyfunctional vinyl compound) having two or more vinyl groups in the molecule, such as polybutadiene, and vinylbenzyl compounds such as styrene and divinylbenzene. Among these, preferred is the compound having two or more carbon-carbon double bonds in the molecule, and specific examples thereof include TAIC, a polyfunctional (meth)acrylate compound, a modified PPE resin, a polyfunctional vinyl compound, and a divinylbenzene compound. Using these compounds is considered to allow a cross-link to be more suitably formed by a curing reaction, and can further increase the heat resistance of a cured product of the curable resin composition. Also, these may be used singly or in combination of two or more thereof. A compound having one carbon-carbon unsaturated double bond in the molecule may also be combined for use. An example of the compound having one carbon-carbon unsaturated double bond in the molecule includes a compound having one vinyl group in the molecule (monovinyl compound).

Examples of the thermoplastic resins can include polystyrene, a polyphenylene ether resin, a polyetherimide resin, a polyethersulfone resin, a PPS resin, a polycyclopentadiene resin, a polycycloolefin resin, and the like, known thermoplastic elastomers (for example, a styrene-ethylene-propylene copolymer, a styrene-ethylene-butylene copolymer, a styrene-butadiene copolymer, a styrene-isoprene copolymer, a hydrogenated styrene-butadiene copolymer, a hydrogenated styrene-isoprene copolymer, and the like), or rubbers (for example, polybutadiene and polyisoprene). Preferred examples thereof include an unmodified or modified polyphenylene ether resin and a hydrogenated styrene-butadiene copolymer.

The flame-retardant resin composition of the present invention may be compounded with a radical polymerization initiator (polymerization catalyst or cross-linking agent) that generates radicals by light and/or heat. Examples of a photopolymerization initiator include benzoins such as benzoin, benzoin methyl ether, benzoin ethyl ether, benzoin propyl ether, and benzoin isobutyl ether; acetophenones such as acetophenone, 2,2-diethoxy-2-phenylacetophenone, 2,2-diethoxy-2-phenylacetophenone, 1,1-dichloroacetophenone, 2-hydroxy-2-methyl-phenylpropan-1-one, diethoxyacetophenone, 1-hydroxycyclohexyl phenyl ketone, and 2-methyl-1-[4-(methylthio)phenyl]-2-morpholinopropan-1-one; anthraquinones such as 2-ethylanthraquinone, 2-tertiary butylanthraquinone, 2-chloroanthraquinone, and 2-amylanthraquinone; thioxanthones such as 2,4-diethylthioxanthone, 2-isopropylthioxanthone, and 2-chlorothioxanthone; ketals such as acetophenone dimethyl ketal and benzyl dimethyl ketal; benzophenones such as benzophenone, 4-benzoyl-4′-methyldiphenyl sulfide, and 4,4′-bismethylaminobenzophenone; and phosphine oxides such as 2,4,6-trimethylbenzoyldiphenylphosphine oxide and bis(2,4,6-trimethylbenzoyl)-phenylphosphine oxide.

Examples of a thermal radical initiator include, but are not limited to, peroxides such as benzoyl peroxide, cumene hydroperoxide, 2,5-dimethylhexane-2,5-dihydroperoxide, 2,5-dimethyl-2,5-di(t-butylperoxy)hexyne-3, di-t-butyl peroxide, t-butylcumyl peroxide, 1,3-bis(butylperoxyisopropyl)benzene, α, α′-bis(t-butylperoxy-m-isopropyl)benzene, 2,5-dimethyl-2,5-di(t-butylperoxy)hexane, dicumyl peroxide, di-t-butylperoxyisophthalate, t-butylperoxybenzoate, 2,2-bis(t-butylperoxy)butane, 2,2-bis(t-butylperoxy)octane, 2,5-dimethyl-2,5-di(benzoylperoxy)hexane, di(trimethylsilyl)peroxide, and trimethylsilyltriphenylsilyl peroxide. Although not a peroxide, 2,3-dimethyl-2,3-diphenylbutane can also be used as the radical polymerization initiator. However, the thermal radical initiator is not limited to these examples, and two or more thereof may be combined for use.

The amount of the radical polymerization initiator compounded is preferably 0.01 to 10 parts by weight and more preferably 0.1 to 5 parts by weight, relative to 100 parts by weight of the phosphorus-containing (meth)acryloyl compound.

The flame-retardant resin composition of the present invention can be compounded with a filler. Examples of the fillers include those added to enhance heat resistance and flame retardancy of a cured product of the curable resin composition, and known fillers can be used, but are not limited thereto. Also, the inclusion of filler enables further enhancement of heat resistance, dimensional stability, flame retardancy, and the like. Specific examples of the fillers include silica such as spherical silica, metal oxides such as alumina, titanium oxide, and mica, metal hydroxides such as aluminum hydroxide and magnesium hydroxide, talc, aluminum borate, barium sulfate, calcium carbonate, and the like. When a metal hydroxide such as aluminum hydroxide or magnesium hydroxide is used, it acts as a flame retardant aid, and can ensure flame retardancy with a little phosphorus content. Among these, preferred are silica, mica, and talc, and more preferred is spherical silica. Also, these may be used singly or in combination of two or more thereof.

The filler may be used as is, or may be surface-treated with a silane coupling agent such as an epoxy silane type or an amino silane type. From the viewpoint of reactivity with the radical polymerization initiator, this silane coupling agent is preferably silane coupling agents such as a vinyl silane type, a methacryloxy silane type, an acryloxy silane type, and a styryl silane types. This enhances adhesive strength with a metal foil and interlayer adhesive strength between resins. Also, instead of a method of preliminarily surface-treating the filler, the above-described silane coupling agent may be added by an integral blending method.

The content of the filler is preferably 10 to 200 parts by mass and more preferably 30 to 150 parts by mass, relative to 100 parts by mass of the total solid content excluding the filler (including organic components such as the monomers and the flame retardant and excluding a solvent).

The flame-retardant resin composition of the present invention may further contain an additive other than those described above. Examples of the additives include, for example, antifoaming agents such as a silicone antifoaming agent and an acrylic acid ester antifoaming agent, a heat stabilizer, an antistatic agent, an ultraviolet absorber, a dye and a pigment, a lubricating agent, and a dispersant such as a wetting dispersant.

A cured product obtained by curing the flame-retardant resin composition of the present invention can be used as a molded product, a laminate, a cast product, an adhesive, a coating film, or a film. For example, a cured product of a semiconductor encapsulation material is a cast product or a molded product, and a method for obtaining a cured product for such applications is a method that includes casting a curable resin composition or molding it using a transfer molding machine, injection molding machine, or the like, and then heating it at 80 to 230° C. for 0.5 to 10 hours to be able to obtain a cured product.

The flame-retardant resin composition of the present invention can also be used as a prepreg. In production of prepreg, a prepreg in varnish form can be prepared for the purpose of impregnating a substrate (fibrous substrate) for forming the prepreg, with the composition, or for the purpose of using it as a circuit board material to form a circuit board, and a resin varnish can be then prepared.

This resin varnish is suitable for circuit boards and can be used as a varnish for circuit board materials. It is to be noted that specific uses of the circuit board materials referred to herein include printed wiring boards, printed circuit boards, flexible printed wiring boards, build-up wiring boards, and the like.

An organic solvent used in the above-described resin varnish is not particularly limited as long as it does not prevent a curing reaction. Examples thereof include, for example, ketones such as acetone, methyl ethyl ketone, and methyl isobutyl ketone; esters such as ethyl acetate, propyl acetate, and butyl acetate; polar solvents such as dimethylacetamide and dimethylformamide; aromatic hydrocarbon solvents such as toluene and xylene; and the like, and they can be used singly or two or more thereof can be mixed and used. From the viewpoint of dielectric properties, aromatic hydrocarbons such as benzene, toluene, and xylene are preferred.

The amount of the organic solvent used when preparing the resin varnish is preferably 5 to 900 parts by weight, more preferably 10 to 700 parts by weight, and particularly preferably 20 to 500 parts by weight, relative to 100 parts by weight of the curable resin composition of the present invention.

A substrate used to prepare the prepreg is a known material, and for example, a glass fiber, a carbon fiber, a polyester fiber, a polyamide fiber, an alumina fiber, and paper, are used singly or in combination of two or more thereof. For these substrates, a coupling agent can be used in order to improve adhesiveness at an interface between the resin and the substrate, if necessary. As the coupling agent, general coupling agents such as a silane coupling agent, a titanate coupling agent, an aluminum coupling agent, and a zircoaluminate coupling agent can be used.

An example of a method for obtaining the prepreg includes a method for impregnating the substrate with the above-described resin varnish and then drying it. The impregnation is carried out by immersion (dipping), coating, or the like. The impregnation can be repeated a plurality of times, if necessary, and in this case, it is also possible to repeat the impregnation using a plurality of solutions with different compositions and concentrations to adjust the final resin composition and resin amount as desired. After impregnation, a prepreg can be obtained by heating and drying at 100 to 180° C. for 1 to 30 minutes. Herein, the amount of resin in the prepreg is preferably 30 to 80% by weight of the resin content.

The curable resin composition of the present invention can also be used as a laminated board. When the laminated board is formed using the prepreg, one or more prepregs are stacked, a metal foil is arranged on one or both sides of the prepreg to form a laminate, and this laminate is heated and pressed to stack and integrate them. Herein, the metal foil can be a single metal foil such as copper, aluminum, brass, and nickel, an alloy metal foil, or a composite metal foil. The conditions for heating and pressing the laminate can be appropriately adjusted so that the curable resin composition is cured, however, when the pressure is too low, air bubbles may remain inside the obtained laminate board, which may result in deterioration of electrical properties, so that the laminate is preferably pressed under conditions that satisfy its moldability. For example, a temperature can be set to 180 to 250° C., pressure to 49.0 to 490.3 N/cm2 (5 to 50 kgf/cm2), and a heating and pressing time to 40 to 240 minutes, respectively. Furthermore, using the single-layer laminated board thus obtained as an inner layer material, a multilayer board can be produced. In this case, a circuit is first formed on the laminated board by an additive method, a subtractive method, or the like, and a surface of the formed circuit is then subjected to blackening treatment with an acid solution to obtain the inner layer material. An insulating layer is formed on one or both circuit-formed surfaces of this inner layer material, using a resin sheet, a metal foil with a resin, or a prepreg, as well as a conductor layer is formed on the surface of the insulating layer to form a multilayer board.

The curable composition of the present invention can also be used in a build-up film. An example of a method for producing the build-up film from the resin composition of the present invention includes a method for coating a surface of a support film with the above-described resin varnish followed by drying it to form an insulating layer in film form. The insulating layer in film form thus formed can be used as a build-up film for multilayer printed wiring boards.

### EXAMPLES

Next, the present invention will be described with reference to Examples, but the present invention is not limited thereto. The parts in each Example are all represented as parts by weight.

Note that the physical properties of each cured samples in Examples were measured by the following methods.
(1) Molecular weight and molecular weight distribution of polymer: The molecular weight and molecular weight distribution of phosphorus-containing phenolic compounds (polymer) were measured using GPC (HLC-8120GPC manufactured by TOSOH CORPORATION) with tetrahydrofuran as the solvent, a flow rate of 1.0 ml/min, a column temperature of 38° C., with a calibration curve based on monodisperse polystyrenes.
(2) Hydroxyl equivalent: Approximately 6 mg/eq of sample was precisely weighed into a 100 mL flask equipped with a stopper, and 3 mL of a mixed reagent of acetic anhydride/pyridine=3/1 (volume ratio) was added. A cooling tube was attached to the flask, and the mixture was heated to reflux on a hot plate for 5 minutes, cooled for 5 minutes, and then 1 mL of water was added thereto.

The liquid was subjected to potentiometric titration with a 0.5 mol/L KOH/MeOH solution to calculate the hydroxyl equivalent.
(3) Phosphorus content: Sulfuric acid, hydrochloric acid, and perchloric acid were added to the sample, which was then heated and wet-ashed to convert all phosphorus atoms into orthophosphoric acid. Metavanadate and molybdate were reacted in a sulfuric acid acidic solution, and an absorbance of the resulting phosphorus vanadate-molybdate complex at 420 nm was measured. A phosphorus atom content was calculated using a calibration curve preliminarily prepared using potassium dihydrogen phosphate, and the obtained content was represented as %.
(4) Glass transition temperature: It was calculated from the amount of a baseline shift at a rate of temperature rise of 10° C./min using differential scanning calorimetry (manufactured by Hitachi High-Tech Science Corporation).
(5) Relative permittivity and dielectric loss tangent: The dielectric constant (Dk) and dielectric loss tangent (Df) at a frequency of 1 GHz were calculated by the capacitance method using a material analyzer (manufactured by AGILENT Technologies, Inc.) in accordance with the IPC-TM-650 2.5.5.9 Standard, under an environment of 25° C. and 60% humidity.
(6) Flame retardancy: It was evaluated using the vertical method using five test pieces in accordance with the UL94. The evaluation results were ranked as V-0, V-1, or V-2.

In Synthesis Examples and Examples, the following compounds were used as raw materials.
SP-2060N (phenol novolac resin: hydroxyl equivalent 107 g/eq, manufactured by NIPPON STEEL Chemical & Material Co., Ltd.)
DC-5 (cresol novolac resin: hydroxyl equivalent 121 g/eq, manufactured by NIPPON STEEL Chemical & Material Co., Ltd.)
SN-485 (naphthol aralkyl resin: hydroxyl equivalent 212 g/eq, manufactured by NIPPON STEEL Chemical & Material Co., Ltd.)
Phosphorus oxychloride (manufactured by Tokyo Chemical Industry Co., Ltd.)
Resorcinol (manufactured by Tokyo Chemical Industry Co., Ltd.)
2,6-Dimethylphenol (manufactured by Tokyo Chemical Industry Co., Ltd.)

Synthesis examples and Examples of the first present invention will be described.

### (Synthesis Example 1A) Synthesis of Di-2,6-Xylyl Phosphorochloridate (DXPC)

A 2L four-neck flask equipped with a stirrer, thermometer, and hydrochloric acid collection apparatus (condenser connected to a water scrubber) was filled with 767 g (5 mol) of phosphorus oxychloride (structural formula below),

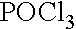

1200 g (9.8 mol) of 2,6-dimethylphenol (structural formula below),

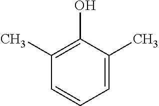

140 g of xylene as a solvent, and 6.2 g (0.065 mol) of magnesium chloride as a catalyst. The resulting mixed solution was gradually heated and raised to a temperature of 160° C. over approximately 3 hours while stirring to react the mixture, and the generated hydrogen chloride gas was collected with the water scrubber. Thereafter, the pressure in the flask was gradually reduced to 20 kPa at the same temperature, and xylene, unreacted phosphorus oxychloride, 2,6-dimethylphenol, and hydrogen chloride as a by-product were removed to obtain 1700 g of a reaction product mainly composed of di-2,6-xylyl phosphorochloridate (DXPC: structural formula below). The chlorine content of the reaction mixture was 10.9% by mass.

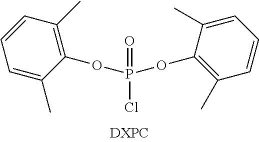 [SMILES: Cc1cccc(C)c1OP(=O)(Cl)Oc1c(C)cccc1C]

### (Synthesis Example 2A) Synthesis of Phosphorus-Containing Phenolic Compound A

A 500 mL four-neck flask equipped with a stirrer, thermometer, and hydrochloric acid collection apparatus (condenser connected to a water scrubber) was filled with 260 g of mesitylene, 58.0 g (0.5 mol) of a phenol novolac resin (structural formula below),

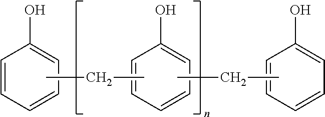

81.8 g (0.25 mol) of DXPC synthesized in Synthesis Example 1A, and 1.2 g (0.01 mol) of anhydrous magnesium chloride and 2.0 g (0.015 mol) of anhydrous aluminum chloride as catalysts. The resulting mixed solution was heated and raised to a temperature of 154° C. over 2 hours while stirring to collect hydrogen chloride generated.

After continuing the reaction for another 2.5 hours, approximately 200 g of mesitylene was recovered under reduced pressure and the pressure was returned to normal pressure. The reaction mixture was cooled to 60° C., having 200 g of ethyl acetate added thereto, washed with an acid, neutralized, and then washed twice with water and the solvent was removed, yielding 113.5 g of a phosphorus-containing phenolic compound A. The weight-average molecular weight (Mw) of the resulting substance was 750, the phosphorus content was 5.5% by weight, and the hydroxyl equivalent was 360 g/eq. It is to be noted that the conversion rate of hydroxyl groups to functional groups containing phosphorus, calculated from the hydroxyl equivalent, was 38.9 mol %.

### (Synthesis Example 3A) Synthesis of Phosphorus-Containing Phenolic Compound B

A 500 mL four-neck flask equipped with a stirrer, thermometer, and hydrochloric acid collection apparatus (condenser connected to a water scrubber) was filled with 260 g of mesitylene, 62.7 g (0.5 mol) of a cresol novolac resin (structural formula below),

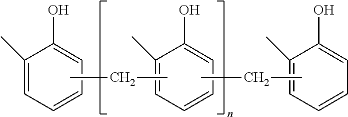

81.8 g (0.25 mol) of DXPC synthesized in Synthesis Example 1A, and 1.2 g (0.01 mol) of anhydrous magnesium chloride and 2.0 g (0.015 mol) of anhydrous aluminum chloride as catalysts. Subsequently, the same operations as in Synthesis Example 2A were performed to obtain 119.4 g of a phosphorus-containing phenolic compound B. The weight-average molecular weight (Mw) of the obtained substance was 1,032, the phosphorus content was 5.0% by weight, and the hydroxyl equivalent was 385 g/eq. It is to be noted that the conversion rate of hydroxyl groups to functional groups containing phosphorus, calculated from the hydroxyl equivalent, was 39.1 mol %.

### (Synthesis Example 4) Synthesis of Phosphorus-Containing Phenol (Compound C)

A 500 mL four-neck flask equipped with a stirrer, thermometer, and hydrochloric acid collection apparatus (condenser connected to a water scrubber) was filled with 260 g of mesitylene and 90.0 g (0.4 mol) of a naphthol aralkyl resin (structural formula below),

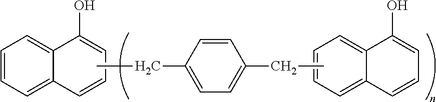

64.8 g (0.2 mol) of DXPC synthesized in Synthesis Example 1A, 0.95 g (0.01 mol) of anhydrous magnesium chloride and 2.0 g (0.015 mol) of anhydrous aluminum chloride as catalysts. Subsequently, the same operations as in Synthesis Example 2A were performed to obtain 125.6 g of a phosphorus-containing phenolic compound C. The weight-average molecular weight (Mw) of the obtained substance was 1,160, the phosphorus content was 3.6% by weight, and the hydroxyl equivalent was 514 g/eq. It is to be noted that the conversion rate of hydroxyl groups to functional groups containing phosphorus, calculated from the hydroxyl equivalent, was 37.6 mol %.

### (Example 1A) Synthesis of Phosphorus-Containing (Meth)Acryloyl Compound A

A glass separable flask equipped with a stirrer, thermometer, cooling tube, and dropping funnel was charged with 100.0 g of phosphorus-containing phenol compound A, 150.0 g of tetrahydrofuran, 28.3 g of triethylamine, and 2.1 g of 4-dimethylaminopyridine, and the mixture was dissolved at room temperature. In a nitrogen atmosphere, 52.3 g of methacrylic anhydride (structural formula below)

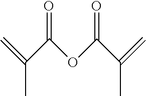

was added dropwise over 1 hour, and the reaction was continued for another 6 hours at 50° C.

Subsequently, the reaction liquid was concentrated and dissolved in 277.7 g of toluene, followed by washing with hydrochloric acid, a sodium carbonate aqueous solution, and water, in this order. After the liquid had been washed with water, it was dehydrated, filtered, and further concentrated by removal of solvent to obtain 214.2 g of a toluene solution of phosphorus-containing methacryloyl compound A. The molecular weight (Mw) of compound A was 750, the phosphorus content was 4.7%, and the presence ratio of a (meth)acryloyl substituent was 61.9 mol %. In this case, the presence ratio of a (meth)acryloyl substituent is a value assuming that all hydroxyl groups were (meth)acryloylated (the same applies to the following Examples).

### (Example 2A) Synthesis of Phosphorus-Containing (Meth)Acryloyl Compound B

A glass separable flask equipped with a stirrer, thermometer, cooling tube, and dropping funnel was charged with 100.0 g of phosphorus-containing phenol compound B, 100.0 g of tetrahydrofuran, 26.4 g of triethylamine, and 2.0 g of 4-dimethylaminopyridine, and the mixture was dissolved at room temperature. In a nitrogen atmosphere, 49.3 g of methacrylic anhydride was added dropwise over 1 hour, and the reaction was continued at 50° C. for another 6 hours.

Subsequently, the reaction liquid was concentrated and dissolved in 275.8 g of toluene, and then washed and concentrated in the same manner as in Example 1A, to obtain 211.9 g of a toluene solution of phosphorus-containing methacryloyl compound B with a solid content of 50%. The molecular weight (Mw) of compound B was 1,130, the phosphorus content was 4.5%, and the presence ratio of a (meth)acryloyl substituent was 60.9 mol %.

### (Example 3A) Synthesis of Phosphorus-Containing (Meth)Acryloyl Compound C

A glass separable flask equipped with a stirrer, thermometer, cooling tube, and dropping funnel was charged with 100.0 g of phosphorus-containing phenol compound C, 150.0 g of tetrahydrofuran, 19.7 g of triethylamine, and 1.5 g of 4-dimethylaminopyridine, and the mixture was dissolved at room temperature. In a nitrogen atmosphere, 36.8 g of methacrylic anhydride was added dropwise over 1 hour, and the reaction was continued at 50° C. for another 6 hours.

Subsequently, the reaction liquid was then concentrated and dissolved in 264.2 g of toluene, and then washed and concentrated in the same manner as in Example 1A to obtain 203.9 g of a toluene solution of phosphorus-containing methacryloyl compound C with a solid concentration of 50%. The molecular weight (Mw) of compound C was 1,260, the phosphorus content was 3.2%, and the presence ratio of a (meth)acryloyl substituent was 62.4 mol %.

### (Comparative Synthesis Example A) Synthesis of Phosphorus-Containing Methacryloyl Compound D

The phosphorus-containing methacryloyl compound D was synthesized according to the method described in JP2022-16422A. Specifically, a 2L four-neck flask equipped with a stirrer, thermometer, and hydrochloric acid collection apparatus (condenser connected to a water scrubber) was filled with 1500 g of phosphorus oxychloride, 611 g of 2,6-dimethylphenol, and 1.2 g of magnesium chloride as a catalyst.

The resulting mixed solution was gradually heated and raised to a temperature of 110° C. over approximately 3 hours while stirring followed by a reaction of the mixture, and the hydrogen chloride generated (a hydrochloric acid gas) was collected with a water scrubber. The pressure in the flask was then gradually reduced to 12 kPa at 120° C., and unreacted phosphorus oxychloride and phenol, as well as hydrogen chloride as a by-product, were removed to obtain 1200 g of mono-2,6-dimethylphenyl phosphorodichloridate.

A 2L four-neck flask equipped with a stirrer, thermometer, dropping funnel, and condenser was filled with 320 g of 2,3,5-trimethylhydroquinone, 135 g of pyridine as a hydrogen chloride scavenger, and 200 g of toluene as a solvent. The dropping funnel was also filled with 203 g of the above-described mono-2,6-dimethylphenyl phosphorodichloridate.

The mixed solution in the four-neck flask was heated to a temperature of 20° C. while stirring, and the mono-2,6-dimethylphenyl phosphorodichloridate in the dropping funnel was dropped over 2 hours while maintaining the same temperature (20° C.). After completion of dropping, the mixture was heated to 65° C. and stirred for 5 hours to obtain a reaction product. The reaction product obtained was washed with dilute hydrochloric acid and water, heated to a temperature of 150° C., followed by reduction of pressure to 2 kPa to distill off water, toluene, and low boiling fractions, and it was cooled to room temperature to obtain 330 g of a phosphorus-containing phenolic compound Das a black-brown solid.

A glass separable flask equipped with a stirrer, thermometer, cooling tube, and dropping funnel was charged with 200 g of phosphorus-containing phenol compound D, 133.2 g of tetrahydrofuran, and 19.5 g of triethylamine, and after the mixture has been dissolved, it was cooled in an ice bath to 5° C. In a nitrogen atmosphere, 78.0 g of methacryloyl chloride was added dropwise over 1 hour and the reaction was continued for another 2 hours.

Subsequently, the reaction liquid was concentrated and dissolved in 601.6 g of toluene, and washed with hydrochloric acid, a sodium carbonate aqueous solution, and water, in this order. After the reaction liquid had been washed with water, it was dehydrated, filtered, and further concentrated by removal of solvent to obtain 227.6 g of a toluene solution of phosphorus-containing methacryloyl compound D. The molecular weight (Mw) of the resulting compound D was 560, and the phosphorus content was 5.2%.

### Examples 4A to 9A and Comparative Examples 1A to 5A

### <Preparation of Curable Resin Composition and Fabrication Of Cured Product>

A varnish was prepared by blending the various components in the ratios shown in Table 1A, and a PET film was coated therewith and dried in an oven at 130° C. for 5 minutes to produce a film of the resin composition.

This film was then pulverized to obtain powder of the resin composition. Furthermore, this powder was then sandwiched between stainless steel mirror plates together with a spacer, molded in a vacuum oven at 210° C. for 90 minutes to obtain a sample of the cured product.

### <Fabrication of Test Piece for Flame Retardancy Evaluation>

Various components were compounded at the ratios shown in Table 1A to prepare a varnish, and this resin varnish was impregnated into glass cloth (7628 type; product number H258, manufactured by Nitto Boseki Co., Ltd.), and the impregnated cloth was then dried by heating at 130° C. for 5 minutes to obtain a prepreg.

Eight sheets of the obtained prepreg and two pieces of copper foil (3EC-III, thickness 35 μm, manufactured by MITSUI MINING & SMELTING CO., LTD.) on top and bottom of the sheets, were overlayed, and the resulting stack was vacuum pressed at 2 MPa under the temperature conditions of 130° C.×15 minutes+190° C.×80 minutes to obtain a laminated board with a thickness of 1.6 mm. The copper foil was etched and cut to obtain a test piece for flame retardancy evaluation.

OPE-2St: A styryl-terminated modified polyphenylene ether resin, manufactured by Mitsubishi Gas Chemical Co., Ltd.
PX-200: An aromatic condensed phosphate ester with a phosphorus content of 9.0%, manufactured by DAIHACHI CHEMICAL INDUSTRY CO., LTD.
Perbutyl P: 1,3-Bis(butylperoxyisopropyl)benzene, manufactured by NOF CORPORATION.

The results are shown in Table 1A.

TABLE 1A

| | | | | | | | Compar- | Compar- | Compar- | Compar- | Compar- |
|---|---|---|---|---|---|---|---|---|---|---|---|
| | | | | | | | ative | ative | ative | ative | ative |
| | Exam- | Exam- | Exam- | Exam- | Exam- | Exam- | Exam- | Exam- | Exam- | Exam- | Exam- |
| | ple 4A | ple 5A | ple 6A | ple 7A | ple 8A | ple 9A | ple 1A | ple 2A | ple 3A | ple 4A | ple 5A |
| OPE-2St | 35.8 | 57.2 | 35.1 | 56.7 | 6.5 | 37.7 | 100.0 | 41.3 | 60.9 | | |
| Phosphorus- | 64.2 | 42.8 | | | | | | | | | |
| containing (meth) | | | | | | | | | | | |
| acryloyl | | | | | | | | | | | |
| compound A | | | | | | | | | | | |
| Phosphorus- | | | 64.9 | 43.3 | | | | | | | |
| containing (meth) | | | | | | | | | | | |
| acryloyl | | | | | | | | | | | |
| compound B | | | | | | | | | | | |
| Phosphorus- | | | | | 93.5 | 62.3 | | | | | |
| containing (meth) | | | | | | | | | | | |
| acryloyl | | | | | | | | | | | |
| compound C | | | | | | | | | | | |
| Phosphorus- | | | | | | | | 58.7 | 39.1 | | |
| containing (meth) | | | | | | | | | | | |
| acryloyl | | | | | | | | | | | |
| compound D | | | | | | | | | | | |
| PX-200 | | | | | | | | | | 33.2 | 22.1 |
| Perbutyl P (phr) | 0.5 | 0.5 | 0.5 | 0.5 | 0.5 | 0.5 | 0.5 | 0.5 | 0.5 | | |
| Phosphorous | 3.0 | 2.0 | 3.0 | 2.0 | 3.0 | 2.0 | 0.0 | 3.0 | 2.0 | 3.0 | 2.0 |
| content (%) | | | | | | | | | | | |
| Glass transition | 151.4 | 163 | 145.9 | 165.4 | 142.5 | 152.7 | 167.1 | 176.6 | 185.3 | 97.7 | 116.7 |
| temperature | | | | | | | | | | | |
| Dielectric | 2.62 | 2.62 | 2.67 | 2.60 | 2.73 | 2.68 | 2.57 | 2.63 | 2.64 | 2.67 | 2.64 |
| constant | | | | | | | | | | | |
| Dielectric loss | 0.0014 | 0.0016 | 0.0011 | 0.0015 | 0.0001 | 0.0008 | 0.0026 | 0.0019 | 0.0021 | 0.0016 | 0.0018 |
| tangent | | | | | | | | | | | |
| Flame retardancy | V-0 | V-0 | V-0 | V-0 | V-0 | V-0 | N.C | V-0 | V-1 | V-0 | V-1 |

* The numerical values represent a compounding amount (solid content value), and 100 parts by weight of toluene were used as a solvent to prepare a varnish.

Next, synthesis examples and Examples of the second invention will be described.

### (Synthesis Example 1B) Synthesis of Di-2,6-Xylyl Phosphorochloridate (DXPC)

A 2L four-neck flask equipped with a stirrer, thermometer, and hydrochloric acid collection apparatus (condenser connected to a water scrubber) was filled with 767 g (5 mol) of phosphorus oxychloride (structural formula below),

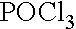

1,200 g (9.8 mol) of 2,6-dimethylphenol (structural formula below),

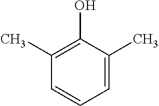

140 g of xylene as a solvent, and 6.2 g (0.065 mol) of magnesium chloride as a catalyst. The resulting mixed solution was gradually heated and raised to a temperature of 160° C. over approximately 3 hours while being stirred to react the solution, and the generated hydrogen chloride gas was collected with a water scrubber. Subsequently, the pressure in the flask was gradually reduced to 20 kPa at the same temperature, and xylene, unreacted phosphorus oxychloride and 2,6-dimethylphenol, and the by-product hydrogen chloride were removed, yielding 1,700 g of a reaction product mainly composed of di-2,6-xylyl phosphorochloridate (DXPC: structural formula below). The reaction mixture also had a chlorine content of 10.9% by mass.

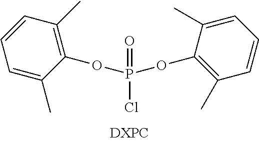 [SMILES: Cc1cccc(C)c1OP(=O)(Cl)Oc1c(C)cccc1C]

### (Synthesis Example 2B) Synthesis of Phosphorus-Containing Phenolic Compound A

A 500 mL four-neck flask equipped with a stirrer, thermometer, and hydrochloric acid collection apparatus (condenser connected to a water scrubber) was filled with 260 g of mesitylene, 58.0 g (0.5 mol) of a phenol novolac resin (structural formula below),

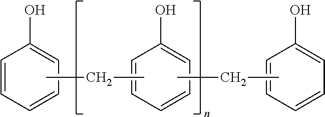

81.8 g (0.25 mol) of DXPC synthesized in Synthesis Example 1B, 1.2 g (0.01 mol) of anhydrous magnesium chloride, and 2.0 g (0.015 mol) of anhydrous aluminum chloride as catalysts. The resulting mixed solution was heated and raised to a temperature of 154° C. over 2 hours while being stirred, and the generated hydrogen chloride was collected. After the reaction was continued for another 2.5 hours, approximately 200 g of mesitylene was collected under reduced pressure, and the pressure was returned to normal. The reaction mixture was cooled to 60° C., added with 200 g of ethyl acetate, and then washed with acid, neutralized, and then washed twice with water to remove the solvent, yielding 113.5 g of phosphorus-containing phenolic compound A. The weight-average molecular weight (Mw) of the resulting substance was 750, the phosphorus content was 5.5% by weight, and the hydroxyl group equivalent was 360 g/eq. It is to be noted that the conversion rate of hydroxyl groups to functional groups containing phosphorus, calculated from the hydroxyl group equivalent, was 38.9 mol %.

### (Synthesis Example 3B) Synthesis of Phosphorus-Containing Phenolic Compound B

A 500 mL four-neck flask equipped with a stirrer, thermometer, and hydrochloric acid collection apparatus (condenser connected to a water scrubber) was filled with 260 g of mesitylene, 62.7 g (0.5 mol) of a cresol novolac resin (structural formula below),

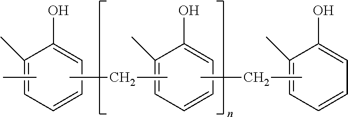

81.8 g (0.25 mol) of DXPC synthesized in Synthesis Example 1B, 1.2 g (0.01 mol) of anhydrous magnesium chloride, and 2.0 g (0.015 mol) of anhydrous aluminum chloride as catalysts. Subsequently, the same operations as in Synthesis Example 2B were performed to obtain 119.4 g of phosphorus-containing phenolic compound B. The weight-average molecular weight (Mw) of the obtained substance was 1,032, the phosphorus content was 5.0% by weight, and the hydroxyl equivalent was 385 g/eq. It is to be noted that the conversion rate of hydroxyl groups to functional groups containing phosphorus, calculated from the hydroxyl group equivalent, was 39.1 mol %.

### (Synthesis Example 4B) Synthesis of Phosphorus-Containing Phenol (Compound C)

A 500 mL four-neck flask equipped with a stirrer, thermometer, and hydrochloric acid collection apparatus (condenser connected to a water scrubber) was filled with 260 g of mesitylene, 90.0 g (0.4 mol) of a naphthol aralkyl resin (structural formula below),

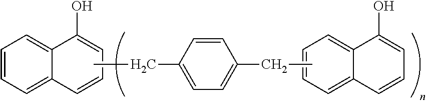

64.8 g (0.2 mol) of DXPC synthesized in Synthesis Example 1B, 0.95 g (0.01 mol) of anhydrous magnesium chloride, and 2.0 g (0.015 mol) of anhydrous aluminum chloride as catalysts. Subsequently, the same operations as in Synthesis Example 2B were performed to obtain 125.6 g of phosphorus-containing phenol compound C. The weight-average molecular weight (Mw) of the obtained substance was 1,160, the phosphorus content was 3.6% by weight, and the hydroxyl equivalent was 514 g/eq. It is to be noted that the conversion rate of hydroxyl groups to functional groups containing phosphorus, calculated from the hydroxyl group equivalent, was 37.6 mol %.

### (Example 1B) Synthesis of Phosphorus-Containing Vinylbenzyl Compound A

A glass separable flask equipped with a stirrer, thermometer, and cooling tube was charged with 100.0 g of phosphorus-containing phenol compound A and 66.7 g of diethylene glycol dimethyl ether, and the mixture was heated to 75° C. in a nitrogen atmosphere to dissolve the mixture. The obtained solution was added with 48.6 g of vinylbenzyl chloride (CMS-P, structural formula below)

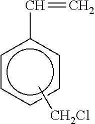

and after the mixture had become homogeneous, the solution was added with 4.5 g of tetrabutylammonium bromide and 115.2 g of a 50% potassium carbonate aqueous solution, followed by reaction for 10 hours.

Subsequently, the reaction liquid was concentrated and dissolved in 319.6 g of toluene, neutralized with a 10% sodium dihydrogen phosphate aqueous solution, and washed with water. The reaction liquid washed with the water was then dehydrated, filtered, and concentrated by removal of solvent to obtain 233.0 g of a 50% toluene solution of phosphorus-containing vinylbenzyl ether compound A. The weight-average molecular weight (Mw) of compound A was 850, the phosphorus content was 4.4%, and the presence ratio of a vinylbenzyl substituent was 61.9 mol %. In this case, the presence ratio of a vinylbenzyl substituent is a value assuming that all hydroxyl groups were vinylbenzylated (the same applies to the following Examples).

### (Example 2B) Synthesis of Phosphorus-Containing Vinylbenzyl Ether Compound B

A glass separable flask equipped with a stirrer, thermometer, and cooling tube was charged with 100.0 g of phosphorus-containing phenol compound B and 66.7 g of diethylene glycol dimethyl ether, and the mixture was heated to 75° C. in a nitrogen atmosphere to dissolve the mixture. The obtained liquid was added with 45.4 g of CMS-P, and after the mixture had become homogeneous, the solution was added with 4.4 g of tetrabutylammonium bromide and 107.7 g of a 50% potassium carbonate aqueous solution, followed by reaction thereof for 10 hours.

Subsequently, the reaction liquid was concentrated and dissolved in 314.0 g of toluene, then neutralized with a 10% sodium dihydrogen phosphate aqueous solution and washed with water. Furthermore, the washed liquid was then dehydrated, filtered, and concentrated by removal of solvent to obtain 229.0 g of a 50% toluene solution of phosphorus-containing vinylbenzyl ether compound B. The weight-average molecular weight (Mw) of compound B was 1,250 and the phosphorus content of 4.2%, and the presence ratio of a vinylbenzyl substituent was 60.9 mol %.

### (Example 3B) Synthesis of Phosphorus-Containing Vinylbenzyl Ether Compound C

A glass separable flask equipped with a stirrer, thermometer, and cooling tube was charged with 100.0 g of phosphorus-containing phenol compound C and 66.7 g of diethylene glycol dimethyl ether, and the mixture was heated to 75° C. in a nitrogen atmosphere to dissolve the mixture. The obtained solution was added with 34.0 g of CMS-P, and after the mixture had become homogeneous, the solution was added with 4.0 g of tetrabutylammonium bromide and 80.7 g of a 50% potassium carbonate aqueous solution followed by reaction thereof for 10 hours.

Subsequently, the reaction liquid was concentrated and dissolved in 293.8 g of toluene, neutralized with a 10% sodium dihydrogen phosphate aqueous solution, and washed with water. The washed liquid was then dehydrated, filtered, and concentrated by removal of solvent to obtain 214.0 g of a 50% toluene solution of phosphorus-containing vinylbenzyl ether compound C. The weight-average molecular weight (Mw) of compound C was 1,350, the phosphorus content was 3.1%, and the presence ratio of a vinylbenzyl substituent of 62.4 mol %.

### Comparative Synthesis Example 1B

A Phosphorus-containing phenol compound D was synthesized according to JP2022-16423A. Specifically, a 2-liter four-neck flask equipped with a stirrer, thermometer, dropping funnel, and condenser was filled with 320 g of 2,3,5-trimethylhydroquinone, 135 g of pyridine as a hydrogen chloride scavenger, and 200 g of toluene as a solvent. 203 g of the above-described DXPC was also added in the dropping funnel. The mixed solution in the four-neck flask was heated to a temperature of 20° C. under stirring, and DXPC in the dropping funnel was dropped over 2 hours while maintaining the same temperature (20° C.). After completion of dropping, the obtained mixed liquid was heated to 65° C. and stirred for 5 hours to obtain a reaction product. The obtained reaction product was washed with dilute hydrochloric acid and water, heated to a temperature of 150° C., underwent removal of water, toluene, and a low boiling point content by distillation under reduced pressure down to 2 kPa, and it was cooled to room temperature to obtain 330 g of phosphorus-containing phenol compound D as a black-brown solid.

A glass separable flask equipped with a stirrer, thermometer, cooling tube, and dropping funnel was charged with 200 g of phosphorus-containing phenol compound D and 133.2 g of diethylene glycol dimethyl ether, and the mixture was heated to 75° C. in a nitrogen atmosphere to dissolve the mixture. The obtained solution was added with 128.6 g of CMS-P, and after the mixed liquid had become homogeneous, the solution was added with 8.2 g of tetrabutylammonium bromide and 213.4 g of a 50% potassium carbonate aqueous solution followed by reaction for 15 hours.

Subsequently, the reaction liquid was concentrated and dissolved in 665.0 g of toluene, neutralized with a 10% sodium dihydrogen phosphate aqueous solution, and washed with water. Furthermore, the obtained liquid was dehydrated, filtered, and concentrated by removal of solvent to obtain 381.5 g of a toluene solution of phosphorus-containing vinylbenzyl ether compound D. The weight-average molecular weight (Mw) of the resulting compound D was 560, and the phosphorus content was 5.2%.

### Examples 4B to 9B and Comparative Examples 1B to 5B

### <Preparation of Curable Resin Composition and Production Of Cured Product>

Various components were compounded at the ratios shown in Table 1B to prepare a varnish, with which a surface of a PET film was coated, and the coated film was dried in an oven at 130° C. for 5 minutes to prepare a film of the resin composition. Next, the film was pulverized to obtain powder of the resin composition. Furthermore, the powder was sandwiched between stainless steel mirror plates together with a spacer, molded in a vacuum oven at 210° C. for 90 minutes to obtain a sample of the cured product.

### <Fabrication of Test Piece for Flame Retardancy Evaluation>

Various components were compounded at the ratios shown in Table 1B to prepare a varnish, which was then impregnated into glass cloth (7628 type; product number H258, manufactured by Nitto Boseki Co., Ltd.), and the impregnated cloth was then dried by heating at 130° C. for 5 minutes to obtain a prepreg.

Eight sheets of the obtained prepreg and two pieces of copper foil (3EC-III, thickness 35 μm, manufactured by MITSUI MINING & SMELTING CO., LTD.) on top and bottom of the sheets, were overlayed, and the resulting stack was vacuum pressed at 2 MPa under the temperature conditions of 130° C.×15 minutes+190° C.×80 minutes to obtain a laminated board with a thickness of 1.6 mm. The copper foil was etched and cut to obtain a test piece for flame retardancy evaluation.

OPE-2St: A styryl-terminated modified polyphenylene ether resin, manufactured by Mitsubishi Gas Chemical Co., Ltd.
PX-200: An aromatic condensed phosphate ester with a phosphorus content of 9.0%, manufactured by DAIHACHI CHEMICAL INDUSTRY CO., LTD.
Perbutyl P: 1,3-bis(butylperoxyisopropyl)benzene, manufactured by NOF CORPORATION

The results are shown in Table 1B.

TABLE 1B

| | | | | | | | Compar- | Compar- | Compar- | Compar- | Compar- |
|---|---|---|---|---|---|---|---|---|---|---|---|
| | | | | | | | ative | ative | ative | ative | ative |
| | Exam- | Exam- | Exam- | Exam- | Exam- | Exam- | Exam- | Exam- | Exam- | Exam- | Exam- |
| | ple 4B | ple 5B | ple 6B | ple 7B | ple 8B | ple 9B | ple 1B | ple 2B | ple 3B | ple 4B | ple 5B |
| OPE-2St | 31.8 | 54.5 | 28.6 | 52.4 | 3.2 | 35.5 | 100.0 | 32.0 | 54.6 | 66.8 | 77.9 |
| Phosphorus- | 68.2 | 45.5 | | | | | | | | | |
| containing | | | | | | | | | | | |
| vinylbenzyl | | | | | | | | | | | |
| compound A | | | | | | | | | | | |
| Phosphorus- | | | 71.4 | 47.6 | | | | | | | |
| containing | | | | | | | | | | | |
| vinylbenzyl | | | | | | | | | | | |
| compound B | | | | | | | | | | | |
| Phosphorus- | | | | | 96.8 | 64.5 | | | | | |
| containing | | | | | | | | | | | |
| vinylbenzyl | | | | | | | | | | | |
| compound C | | | | | | | | | | | |
| Phosphorus- | | | | | | | | 68.0 | 45.4 | | |
| containing | | | | | | | | | | | |
| vinylbenzyl | | | | | | | | | | | |
| compound D | | | | | | | | | | | |
| PX-200 | | | | | | | | | | 33.2 | 22.1 |
| Perbutyl P(phr) | 0.5 | 0.5 | 0.5 | 0.5 | 0.5 | 0.5 | 0.5 | 0.5 | 0.5 | 0.5 | 0.5 |
| Phosphorous | 3 | 2 | 3 | 2 | 3 | 2 | 0 | 3 | 2 | 3 | 2 |
| content(%) | | | | | | | | | | | |
| Glass transition | 160.4 | 171.0 | 155.9 | 172.4 | 150.5 | 159.7 | 167.1 | 167 | 173.9 | 97.7 | 116.7 |
| temperature (° C.) | | | | | | | | | | | |
| Dielectric | 2.70 | 2.67 | 2.67 | 2.63 | 2.73 | 2.65 | 2.57 | 2.64 | 2.58 | 2.67 | 2.64 |
| constant | | | | | | | | | | | |
| Dielectric loss | 0.0016 | 0.0020 | 0.0013 | 0.0019 | 0.0008 | 0.0012 | 0.0026 | 0.0025 | 0.0024 | 0.0016 | 0.0018 |
| tangent | | | | | | | | | | | |
| Flame retardancy | V-0 | V-0 | V-0 | V-0 | V-0 | V-0 | N.C | V-0 | V-0 | V-0 | V-0 |

* The numerical values represent a compounding amount (solid content value), and 100 parts by weight of toluene were used as a solvent to prepare a varnish.

### INDUSTRIAL APPLICABILITY

The phosphorus-containing (meth)acryloyl compound and the phosphorus-containing vinylbenzyl ether compound of the present invention are useful for flame retardation of a plastic material, the thermosetting resin such as an epoxy resin, for use in electric and electronic products, office automation equipment, communication equipment, building materials, and the like, and are particularly useful as flame retardant materials for reducing a transmission loss at higher frequencies accompanying an increase in the amount of information processed of electronic devices.

1. A phosphorus-containing (meth)acryloyl compound represented by general formula (1A): 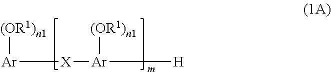
wherein, in the general formula (1A), m is a number of 1 to 20; n1 is each independently a number of 1 to 4; Ar is an aromatic ring having 6 to 30 carbon atoms optionally having a substituent; R1 is each independently a substituent represented by general formula (2A) or general formula (3A), provided that the compound contains at least one substituent represented by the general formula (2A) and at least one substituent represented by the general formula (3A), and X represents a linking group and is each independently oxygen, sulfur, a substituted or unsubstituted alkylene having 1 to 20 carbon atoms, a substituted or unsubstituted cycloalkylene having 3 to 20 carbon atoms, or an aralkylene having 8 to 32 carbon atoms, 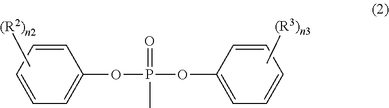
wherein, in the general formula (2A), R2 and R3 are each independently a linear or branched alkyl group having 1 to 5 carbon atoms, and n2 and n3 are each independently a number of 0 to 5, 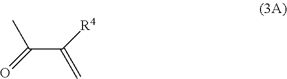
wherein R4 is hydrogen or a methyl group.

2. The phosphorus-containing (meth)acryloyl compound according to claim 1, wherein the compound is represented by the following general formula (4A): 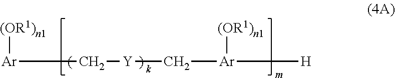
wherein, in the general formula (4A), R1, n1, and m are as defined for the general formula (1A), Y is an aromatic cyclic group having 6 to 30 carbon atoms optionally having a substituent, k is 0 or 1, and Ar represents an aromatic group derived from an aromatic compound represented by the following general formula (5), (6), (7), or (8): 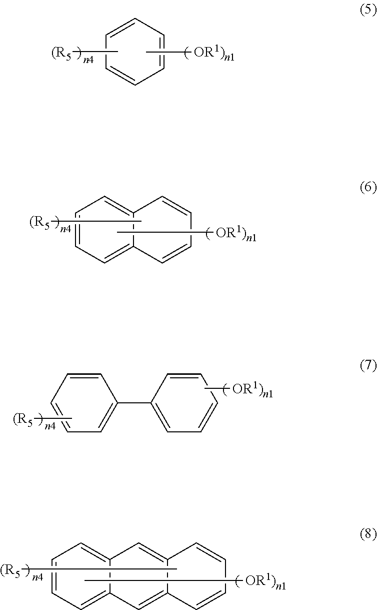
wherein, in the general formulae (5), (6), (7), and (8), R5 is each independently an alkyl group having 1 to 10 carbon atoms, or an alkoxy group having 1 to 10 carbon atoms, n4 is an integer of 0 to 4, and R1 and n1 are as defined for the general formula (1A).

3. The phosphorus-containing (meth)acryloyl compound according to claim 1, wherein the compound has a phosphorus content of 1.5 to 12.0% by weight.

4. A method for producing the phosphorus-containing (meth)acryloyl compound according to claim 1, comprising reacting a phosphorus-containing phenolic compound represented by general formula (9) with one or more of (meth)acrylic acid, a (meth)acryloyl halide, or (meth)acrylic anhydride, 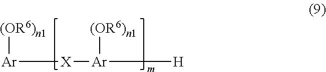
wherein, in the general formula (9), m, n1, Ar, and X are as defined for the general formula (1A), and R6 is hydrogen or the substituent represented by the general formula (2A).

5. A flame-retardant resin composition, obtained by adding one or more of a thermosetting resin or a thermoplastic resin to the phosphorus-containing (meth)acryloyl compound according to claim 1.

6. A laminated board for electronic circuit boards, obtained by using the flame-retardant resin composition according to claim 5.

7. A phosphorus-containing vinylbenzyl ether compound represented by general formula (1B): 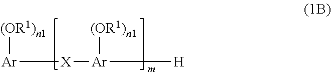
wherein, in the general formula (1B), m is a number of 1 to 20, n1 is each independently a number of 1 to 4, Ar is an aromatic ring having 6 to 30 carbon atoms optionally having a substituent, R1 is each independently a substituent represented by general formula (2B) or a vinylbenzyl group represented by general formula (3B), provided that the compound contains at least one substituent represented by the general formula (2B) and at least one substituent represented by the general formula (3B), and X represents a linking group and is each independently oxygen, sulfur, a substituted or unsubstituted cycloalkylene having 3 to 20 carbon atoms, or an aralkylene having 8 to 32 carbon atoms, 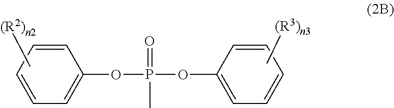
wherein, in the general formula (2B), R2 and R3 are each independently a linear or branched alkyl group having 1 to 5 carbon atoms, and n2 and n3 are each independently a number of 0 to 5.

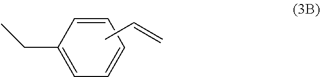

8. The phosphorus-containing vinylbenzyl ether compound according to claim 7, wherein the compound is represented by the following general formula (4B): 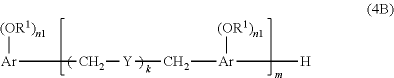
wherein, in the general formula (4B), R1, n1, and m are as defined for the general formula (1B), Y is an aromatic cyclic group having 6 to 30 carbon atoms optionally having a substituent, k is 0 or 1, and Ar represents an aromatic group derived from an aromatic compound represented by the following general formula (5), (6), (7), or (8): 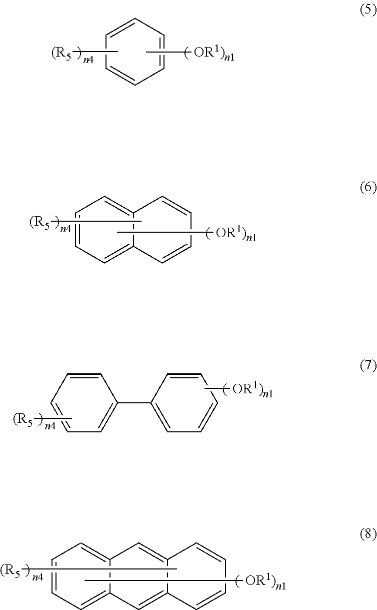
wherein, in the general formulae (5), (6), (7), and (8), R5 is each independently an alkyl group having 1 to 10 carbon atoms, or an alkoxy group having 1 to 10 carbon atoms, n4 is an integer of 0 to 4, and R1 and n1 are as defined for the general formula (1B).

9. The phosphorus-containing vinylbenzyl ether compound according to claim 7, wherein the compound has a phosphorus content of 1.5 to 12.0% by weight.

10. A method for producing the phosphorus-containing vinylbenzyl ether compound according to claim 7, comprising reacting a phosphorus-containing phenolic compound represented by general formula (9) with a vinylbenzyl halide, 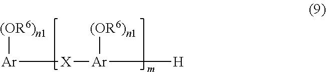
wherein, in the general formula (9), m, n1, Ar, and X are as defined for the general formula (1B), and R6 is hydrogen or the substituent represented by the general formula (2B).

11. A flame-retardant resin composition, obtained by adding one or more of a thermosetting resin or a thermoplastic resin to the phosphorus-containing vinylbenzyl ether compound according to claim 7.

12. A laminated board for electronic circuit boards, obtained by using the flame-retardant resin composition according to claim 11.
